(19) United States
(12) Patent Application Publication
(10) Pub. No.: US 2026/0353955 A1
(43) Pub. Date: Nov. 5, 2026

(54) DISPLAY PANEL AND DISPLAY DEVICE

(71) Applicant: Shanghai AVIC Optoelectronics Co., Ltd., Shanghai (CN)

(72) Inventors: Zhicheng Pan, Shanghai (CN); Lina Sun, Shanghai (CN); Dandan Qin, Shanghai (CN)

(73) Assignee: Shanghai AVIC Optoelectronics Co., Ltd., Shanghai (CN)

(21) Appl. No.: 19/723,306

(22) Filed: Jun. 29, 2026

(30) Foreign Application Priority Data
Dec. 31, 2025 (CN) 202512059689.6

(51) Int. Cl. H10K 59/131; H10H 29/49; H10K 59/35

(52) U.S. Cl. CPC H10K 59/131; H10H 29/49; H10K 59/35

(57) ABSTRACT

Provided are a display panel and a display device. The display panel includes a plurality of pixel units arranged in an array, a plurality of power signal lines, and a plurality of data signal lines. A pixel unit includes a plurality of sub-pixels of different emission colors. A sub-pixel includes a pixel circuit and a light-emitting element electrically connected to each other. Pixel circuits in two adjacent columns are electrically connected to the same data signal line. The power signal lines are arranged in the row direction of the pixel units and extend in the column direction of the pixel units. The distance between two adjacent power signal lines is Ll. Ll≥Lp. Lp is the dimension of one pixel unit in the row direction.

### CROSS-REFERENCE TO RELATED APPLICATION

This application claims priority to Chinese Patent Application No. 202512059689.6 filed Dec. 31, 2025, the disclosure of which is incorporated herein by reference in its entirety.

### TECHNICAL FIELD

The present disclosure relates to the field of display technology and, in particular, to a display panel and a display device.

### BACKGROUND

With the development of display technology, the requirements for the resolution and size of display panels have become increasingly high. This has made high resolution, large size, and high refresh rate become key development trends for current display panels.

Currently, a display panel with relatively high resolution is usually provided with a relatively great number of sub-pixels and a relatively great number of signal lines. For example, the display panel is provided with a relatively great number of data signal lines and a relatively great number of power signal lines. These data signal lines and power signal lines are electrically connected to the corresponding sub-pixels to supply data signals and power signals to the sub-pixels, respectively, thereby driving the sub-pixels to emit light and perform display.

However, the relatively great number of data signal lines and the relatively great number of power signal lines may lead to issues such as an increase in bezel wiring and the number of driver chips in the display panel, not helping with the narrow bezel and low cost of the display panel. Moreover, at the start moment of one frame of image, the power signal lines have instantaneously large currents. The instantaneously large currents cause voltage fluctuations in power signals transmitted by the power signal lines. The power signals are coupled to the sub-pixels. Therefore, the sub-pixels may generate abnormal display and light emission, resulting in a screen flicker problem of the display panel and affecting the display effect of the display panel.

### SUMMARY

The present disclosure provides a display panel and a display device to alleviate the screen flicker problem and improve the display effect of the display panel.

In a first aspect, the present disclosure provides a display panel. The display panel includes a plurality of pixel units arranged in an array, a plurality of power signal lines, and a plurality of data signal lines.

A pixel unit among the plurality of pixel units includes a plurality of sub-pixels of different emission colors, and a sub-pixel among the plurality of sub-pixels includes a pixel circuit and a light-emitting element electrically connected to each other.

Pixel circuits in two adjacent columns are electrically connected to a same data signal line.

The plurality of power signal lines are arranged in a row direction of the plurality of pixel units and extend in a column direction of the plurality of pixel units, and a distance between two adjacent power signal lines is Ll, Ll ≥Lp, and Lp is a dimension of one of the plurality of pixel units in the row direction.

In a second aspect, an embodiment of the present disclosure provides a display device including the display panel described in the first aspect.

### BRIEF DESCRIPTION OF DRAWINGS

FIG. 1 is a structural diagram of a display panel in the related art.

FIG. 2 is a structural diagram of a display panel according to an embodiment of the present disclosure.

FIG. 3 is a structural diagram of a sub-pixel according to an embodiment of the present disclosure.

FIG. 4 is a drive timing diagram of a sub-pixel according to an embodiment of the present disclosure.

FIG. 5 is a structural diagram of another display panel according to an embodiment of the present disclosure.

FIG. 6 is a structural diagram of another display panel according to an embodiment of the present disclosure.

FIG. 7 is a structural diagram of another display panel according to an embodiment of the present disclosure.

FIG. 8 is a structural diagram of another display panel according to an embodiment of the present disclosure.

FIG. 9 is a structural diagram of another display panel according to an embodiment of the present disclosure.

FIG. 10 is a top view illustrating the partial structure of a display panel according to an embodiment of the present disclosure.

FIG. 11 is a top view illustrating the partial structure of another display panel according to an embodiment of the present disclosure.

FIG. 12 is a top view illustrating the partial structure of a display panel according to an embodiment of the present disclosure.

FIG. 13 is a diagram illustrating the layer structure of a display panel according to an embodiment of the present disclosure.

FIG. 14 is a structural diagram of another display panel according to an embodiment of the present disclosure.

FIG. 15 is a diagram of a corresponding relationship curve between visual perception intensity and light wavelength according to an embodiment of the present disclosure.

FIG. 16 is a structural diagram of sub-pixels in a row in a display panel according to an embodiment of the present disclosure.

FIG. 17 is a structural diagram of sub-pixels in a row in another display panel according to an embodiment of the present disclosure.

FIG. 18 is a structural diagram of sub-pixels in a row in another display panel according to an embodiment of the present disclosure.

FIG. 19 is a structural diagram of sub-pixels in a row in another display panel according to an embodiment of the present disclosure.

FIG. 20 is a structural diagram of sub-pixels in a row in another display panel according to an embodiment of the present disclosure.

FIG. 21 is a structural diagram of sub-pixels in a row in another display panel according to an embodiment of the present disclosure.

FIG. 22 is a structural diagram of sub-pixels in a row in another display panel according to an embodiment of the present disclosure.

FIG. 23 is a structural diagram of sub-pixels in a row in another display panel according to an embodiment of the present disclosure.

FIG. 24 is a structural diagram of sub-pixels in a row in another display panel according to an embodiment of the present disclosure.

FIG. 25 is a structural diagram of sub-pixels in a row in another display panel according to an embodiment of the present disclosure.

FIG. 26 is a structural diagram of sub-pixels in a row in another display panel according to an embodiment of the present disclosure.

FIG. 27 is a structural diagram of sub-pixels in a row in another display panel according to an embodiment of the present disclosure.

FIG. 28 is a structural diagram of sub-pixels in a row in another display panel according to an embodiment of the present disclosure.

FIG. 29 is a structural diagram of sub-pixels in a row in another display panel according to an embodiment of the present disclosure.

FIG. 30 is a structural diagram of sub-pixels in a row in another display panel according to an embodiment of the present disclosure.

FIG. 31 is a structural diagram of sub-pixels in a row in another display panel according to an embodiment of the present disclosure.

FIG. 32 is a top view illustrating the partial structure of a display panel according to an embodiment of the present disclosure.

FIG. 33 is a structural diagram of another display panel according to an embodiment of the present disclosure.

FIG. 34 is a diagram illustrating the layer structure of another display panel according to an embodiment of the present disclosure.

FIG. 35 is a diagram illustrating the layer structure of another display panel according to an embodiment of the present disclosure.

FIG. 36 is a diagram illustrating the layer structure of another display panel according to an embodiment of the present disclosure.

FIG. 37 is a structural diagram of a display device according to an embodiment of the present disclosure.

### DETAILED DESCRIPTION

The present disclosure is further described in detail below in conjunction with the drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

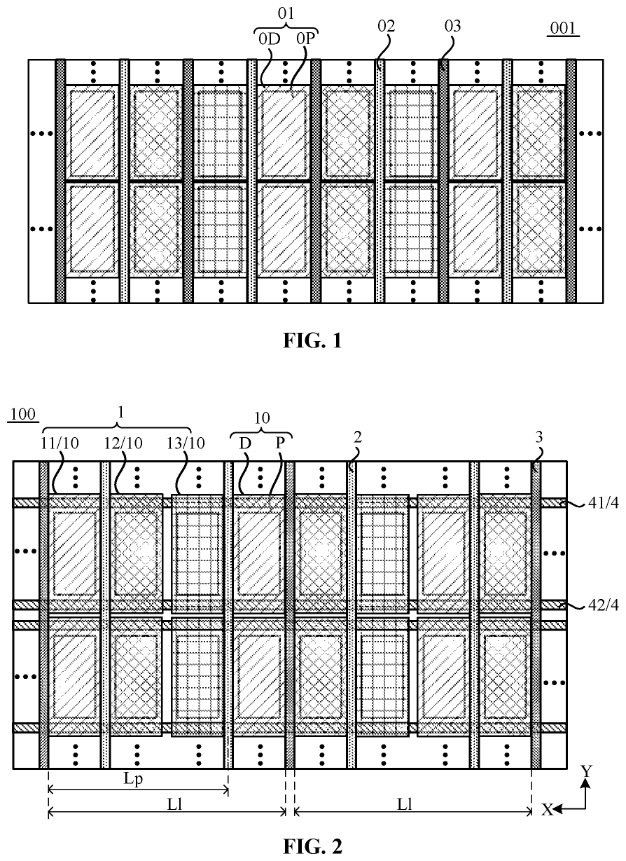

Self-luminous display panels, such as organic light-emitting diode display panels, micro light-emitting diode display panels and mini light-emitting diode display panels, are favored by various display devices. This is their ability to deliver vivid and true colors and a wide color gamut with no need for a backlight. Additionally, they enable lightweight designs and support flexible forms such as folding and curling, offering a high degree of design freedom. FIG. 1 is a structural diagram of a display panel in the related art. As shown in FIG. 1, the display panel 001 includes a plurality of sub-pixels 01 arranged in an array and a plurality of signal lines. A sub-pixel 01 may include a pixel circuit 0P and a light-emitting element 0D electrically connected to each other. The pixel circuit 0P may drive the light-emitting element 0D to emit light and perform display. The signal lines may at least include data signal lines 02 and power signal lines 03. The pixel circuit 0P is electrically connected to a data signal line 02 and a power signal line 03 separately to receive a data signal supplied by the data signal line 02, to receive a power signal 03 transmitted by the power signal line 03, and to supply a corresponding drive signal to the light-emitting element 0D to drive the light-emitting element 0D to emit light and perform display according to the power signal and the data signal.

Currently, in the high-resolution and large-size display panel 100, the data signal lines 02 and the power signal lines 03 are alternately distributed between pixel circuits 0P of sub-pixels 01 in two adjacent columns. Moreover, the same data signal line 02 is electrically connected to pixel circuits 0P of sub-pixels 01 in two adjacent columns, and the pixel circuits 0P electrically connected to the same data signal line 02 receive different gate signals. That is, two pixel circuits 0P electrically connected to the same data signal line 02 and located in the same row receive different gate signals, respectively, implementing the dual gate line driving (DGLD) technology. In this case, pixel circuits 0P electrically connected to the same data signal line 02 can be scanned in a time-division manner so that the data signal line 02 can supply data signals to the pixel circuits 0P electrically connected the data signal line 02 in a time-division manner. Moreover, one power signal line 03 is electrically connected to pixel circuits 0P of sub-pixels 01 in one or two columns and controls, in a time-division manner, components in the pixel circuits 0P electrically connected to the same power signal line 03 to be turned on so that power signals transmitted by the power signal line 03 can be written to the pixel circuits 0P electrically connected to the power signal line 03 in a time-division manner.

However, when the data signal lines 02 and the power signal lines 03 are alternately distributed between pixel circuits 0P of sub-pixels 01 in two adjacent columns, no data signal line 02 is disposed between a power signal line 03 and a pixel circuit 0P, and no power signal line 03 is disposed between a data signal line 02 and a pixel circuit 0P. A data signal line 02 may be directly adjacent to pixel circuits 0P located on two opposite sides of the data signal line 02. A power signal line 03 may be directly adjacent to pixel circuits 0P located on two opposite sides of the power signal line 03. In this case, a parasitic capacitance may be formed between a data signal line 02 and pixel circuits 0P located on two opposite sides of the data signal line 02, and a parasitic capacitance may be formed between a power signal line 03 and pixel circuits 0P located on two opposite sides of the power signal line 03.

Additionally, a data signal transmitted by the data signal line 02 usually varies with the display brightness of a sub-pixel 01 so that the transmission of the data signal line 02 may be designed according to actual needs. A power signal transmitted by the power signal line 03 is usually a fixed signal so that at the start moment of a frame of image, when a component electrically connected to the power signal line 03 in the pixel circuit 0P is turned on, the power signal transmitted by the power signal line 03 may quickly charge the corresponding node in the pixel circuit 0P. In this case, an instantaneously large current is generated on the power signal line 03, making the power signal transmitted by the power signal line 03 generate an instantaneous voltage fluctuation. The parasitic capacitance is formed between the power signal line 03 and the pixel circuits 0P on two opposite sides of the power signal line 03 so that a power signal with an instantaneously large current and voltage fluctuation on the power signal line 03 is coupled to the pixel circuits 0P on two opposite sides of the power signal line 03. The pixel circuits 0P drive light-emitting elements 0D electrically connected to the pixel circuits 0P to emit light and perform display due to the existence of the coupling signal, thus causing sub-pixels 01 to generate abnormal display and light emission. Therefore, when developing the DGLD technology, the applicant found in the research process that the pixel circuits 0P of the sub-pixels 01 are directly adjacent to the power signal line 03. In this case, at the start moment of a frame of image, the sub-pixels 01 in the display panel 001 all generate abnormal display and light emission, causing the display panel 001 to exhibit an instantaneously bright image, leading to the screen flicker problem of the display panel 001, and affecting the display effect of the display panel 001.

To resolve the preceding problems, an embodiment of the present disclosure provides a display panel. The display panel includes a plurality of pixel units arranged in an array, a plurality of power signal lines, and a plurality of data signal lines. A pixel unit includes a plurality of sub-pixels of different emission colors. A sub-pixel includes a pixel circuit and a light-emitting element electrically connected to each other. Pixel circuits in two adjacent columns are electrically connected to the same data signal line. The power signal lines are arranged in the row direction of the pixel units and extend in the column direction of the pixel units. The distance between two adjacent power signal lines is Ll. Ll ≥Lp. Lp is the dimension of one pixel unit in the row direction.

With the adoption of the preceding technical solutions, the same data signal line is electrically connected to sub-pixels in two adjacent columns, correspondingly reducing the number of data signal lines disposed in the display panel, thus reducing the number of bezel wiring and the number of driver chips in the display panel, thereby helping with the narrow bezel of the display panel, and reducing the driving cost of the display panel. Moreover, a power signal line is electrically connected to at least sub-pixels of pixel units in the same column, and the distance between two adjacent power signal lines is greater than the dimension of one pixel unit in the row direction; compared with the case where one power signal line is provided for sub-pixels in two adjacent columns, such an arrangement reduces the number of power signal lines disposed in the display panel, also reduces the number of bezel wiring in the display panel, and thus help with the narrow bezel of the display panel. Additionally, a reduction in the number of power signal lines disposed in the display panel reduces the number of sub-pixels immediately adjacent to the power signal lines, reduces the number of sub-pixels coupled to the power signal lines, thus reduces the number of sub-pixels that abnormally emit light and perform display, thereby alleviates the screen flicker problem occurring at the start moment of one frame of image, and improves the display effect of the display panel.

The preceding is the core idea of the present disclosure. Based on the embodiments of the present disclosure, all other embodiments obtained by those of ordinary skill in the art without creative work are within the scope of the present disclosure. Hereinafter, the technical solutions in the embodiments of the present disclosure are described clearly and completely in conjunction with the drawings in the embodiments of the present disclosure.

FIG. 2 is a structural diagram of a display panel according to an embodiment of the present disclosure. As shown in FIG. 2, the display panel includes a plurality of pixel units 1 arranged in an array, a plurality of power signal lines 3, and a plurality of data signal lines 2. A pixel unit 1 includes a plurality of sub-pixels 10 of different emission colors. A sub-pixel 10 includes a pixel circuit P and a light-emitting element D electrically connected to each other. Pixel circuits P in two adjacent columns are electrically connected to the same data signal line 2. The power signal lines 3 are arranged in the row direction X of the pixel units 1 and extend in the column direction Y of the pixel units 1. The distance between two adjacent power signal lines 3 is Ll. Ll≥Lp. Lp is the dimension of one pixel unit 1 in the row direction X.

It may be understood that a pixel unit 1 may be the smallest repetition unit in the display panel or a basic visual unit when the display panel performs image display. The pixel unit 1 may include a plurality of sub-pixels 10 of different emission colors. The number of sub-pixels 10 in the pixel unit 1 and arranged in the row direction X may be greater than or equal to 3, which may be specifically designed according to actual needs and is not specifically limited in the embodiments of the present disclosure. In an exemplary embodiment, the pixel unit 1 may include a first sub-pixel 11 whose emission color is a first color, a second sub-pixel 12 whose emission color is a second color, and a third sub-pixel 13 whose emission color is a third color. The first sub-pixel 11, the second sub-pixel 12, and the third sub-pixel 13 are arranged in the row direction. The first color, the second color, and the third color may be red, green, and blue, respectively. It may be understood that in some embodiments, some of the sub-pixels 10 in the pixel unit 1 may also have the same color. For example, the pixel unit 1 may include a first sub-pixel 11, a third sub-pixel 13, and two second sub-pixels 12, which is not limited in the present disclosure. In a sub-pixel 10, the pixel circuit P is electrically connected to the light-emitting element D. The pixel circuit P is electrically connected to a data signal line 2 so that the pixel circuit P can receive a data signal transmitted by the data signal line 2 and supplies a corresponding drive signal to the light-emitting element D according to the received data signal to drive the light-emitting element D to emit light and perform display. The display and light emission of light-emitting elements D in sub-pixels 10 of different colors are combined with each other so that the display panel 100 can present a colorful display image.

The light-emitting element D may include a current-driven element such as an organic light-emitting diode, a micro light-emitting diode, or a mini light-emitting diode. The pixel circuit P may be composed of an active component and/or a passive component to be able to convert a voltage signal of the data signal transmitted by the data signal line 2 into a current signal, thus driving the light-emitting element D electrically connected to the pixel circuit P to accurately emit light. The active component may include, but is not limited to, a transistor. The passive component may include at least one of a capacitor, a resistor, or an inductor. It needs to be noted that the specific structure of the pixel circuit P is not limited in the embodiments of the present disclosure on the premise that the pixel circuit P can drive the light-emitting element D to accurately emit light.

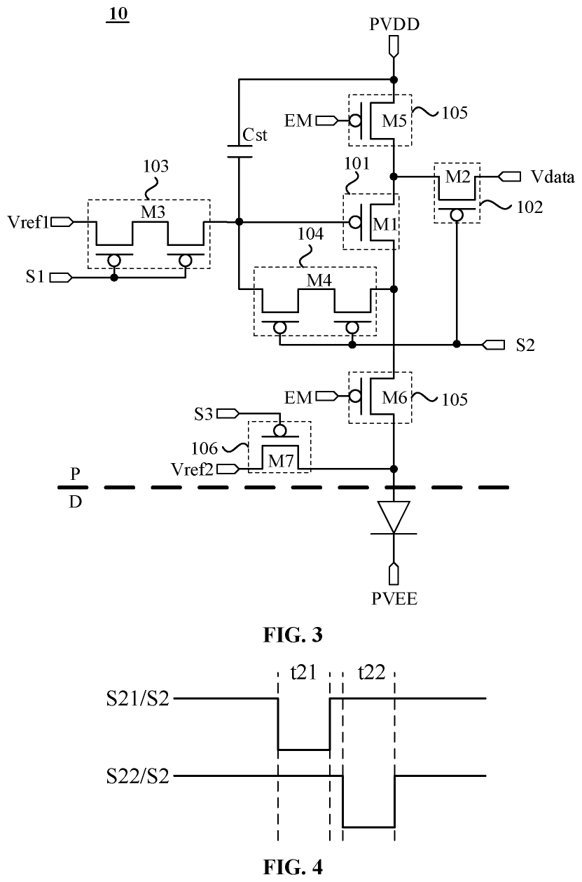

In an optional embodiment, FIG. 3 is a structural diagram of a sub-pixel according to an embodiment of the present disclosure. Referring to FIGS. 2 and 3, the pixel circuit P at least includes a drive module 101 and a data write module 102. The data write module 102 is electrically connected to a data signal line 2 and the drive module 101 separately. The data write module 102 can control the supply of the data signal Vdata transmitted by the data signal line 2 to the drive module 101. The drive module 101 can selectively supply a drive current to the light-emitting element D according to the written data signal Vdata to drive the light-emitting element D to emit light and perform display.

Additionally, the display panel 100 may further include a plurality of first gate signal lines 4. The data write module 102 in the pixel circuit P is also electrically connected to a first gate signal line 4 to receive a first gate signal S2 transmitted by the first gate signal line 4. Moreover, when the first gate signal S2 is at an effective level, the data signal Vdata transmitted by the data signal line 2 is controlled to be supplied to the drive module 101 to implement the writing of the data signal Vdata.

It may be understood that pixel circuits P in two adjacent columns are electrically connected to the same data signal line 2. That is, one data signal line 2 may be electrically connected to data write modules 102 of pixel circuits P in two adjacent columns so that one data signal line 2 can supply data signals Vdata to data write modules 102 of two adjacent pixel circuits P in one row. Therefore, no data signal line 2 needs to be provided for pixel circuits P in the same row respectively, reducing the number of data signal lines 2 disposed in the display panel 100, reducing the occupied space of the data signal lines 2, relatively increasing the arrangement space of pixel circuits P, and improving the resolution of the display panel 100. Moreover, data signals are usually supplied by the driver chips. The driver chips are usually disposed in the bezel region of the display panel 100. When the number of data signal lines 2 is reduced, such an arrangement reduces the signal wiring in the bezel region for connecting the data signal lines 2 to the driver chips, reduces the number of driver chips disposed in the bezel region, thus help with the narrow bezel of the display panel 100, and reduce the driving cost of the display panel 100.

Accordingly, when a data signal line 2 is electrically connected to pixel circuits P in two adjacent columns, in order to guarantee that the pixel circuits P receive data signals Vdata accurately, the data signal line 2 needs to transmit, in a time-division manner, data signals Vdata of the pixel circuits P electrically connected to the data signal line 2 and write, in a time-division manner, the data signals Vdata into the pixel circuits P electrically connected to the data signal line 2. In this case, data write modules 102 of pixel circuits P electrically connected to the same data signal line 2 should be electrically connected to different first gate signal lines 4, respectively. That is, data write modules 102 of two pixel circuits P located in the same row and electrically connected to the same data signal line 2 should be electrically connected to different first gate signal lines 4, respectively.

Multiple first gate signal lines 4 may transmit the effective levels of first gate signals S2 in a time-division manner to control pixel circuits P electrically connected to different first gate signal lines 4 respectively to write data signals in a time-division manner. Data write modules 102 of two pixel circuits P located in the same row and electrically connected to the same data signal line 2 are electrically connected to different first gate signal lines 4, respectively so that data signals Vdata of two pixel circuits P located in the same row and electrically connected to the same data signal line 2 can be written in a time-division manner. For example, in a first sub-pixel 11 and a second sub-pixel 12 that are located in the same row and adjacent to each other, data write modules 101 of pixel circuits P are electrically connected to the same data signal line 2. In this case, the data write module 101 of the pixel circuit P in the first sub-pixel 11 may be electrically connected to the first first gate signal line 41, and the data write module 101 of the pixel circuit P in the second sub-pixel 12 may be electrically connected to the second first gate signal line 42. The effective level duration t22 of a first gate signal S22 transmitted by the second first gate signal line 42 may be located after the effective level duration t21 of a first gate signal S21 transmitted by the first first gate signal line 41 (as shown in FIG. 4). With this arrangement, when the first gate signal S21 transmitted by the first first gate signal line 41 and the first gate signal S 22 transmitted by the second first gate signal line 42 are at an effective level and an ineffective level, respectively, the data write module 102 of the first sub-pixel 11 may write a data signal Vdata transmitted by the data signal line 2 to the first sub-pixel 11. After the first sub-pixel 11 completes the writing of the data signal Vdata, the first gate signal S21 transmitted by the first first gate signal line 41 becomes at an ineffective level, and the second first gate signal line 42 transmits the effective level of the first gate signal S22. The data write module 102 of the second sub-pixel 12 may write a data signal Vdata transmitted by the data signal line 2 to the second sub-pixel 12 so that two sub-pixels 10 electrically connected to the same data signal line 2 and located in the same row can write data signals in a time-division manner.

It may be understood that two sub-pixels 10 electrically connected to the same data signal line 2 and located in the same row are electrically connected to different first gate signal lines 4, respectively. In such way, sub-pixels in one row need to be connected two first gate signal lines, enabling the display panel 100 to implement the dual gate line driving (DGLD) technology.

Continuing to refer to FIGS. 2 and 3, the drive module 101 may be further coupled to a power signal line 3 so that a power signal transmitted by the power signal line 3 can be selectively supplied to the drive module 101. Moreover, when the power signal transmitted by the power signal line 3 is supplied to the drive module 101, the drive current generated by the drive module 101 according to the data signal Vdata can be supplied to the light-emitting element D to enable the light-emitting element D to emit light and perform display. The power signal transmitted by the power signal line 3 may be a positive power signal PVDD or a negative power signal PVEE, which may be specifically designed according to actual needs and is not specifically limited in the embodiments of the present disclosure. For ease of description, without special limitation, in all the embodiments of the present disclosure, an example in which the power signal transmitted by the power signal line 3 is a positive power signal PVDD is taken to exemplarily describe the technical solutions of the embodiments of the present disclosure.

Accordingly, a light emission control module 105 may be further disposed in the pixel circuit P so that the drive module 101 is electrically connected to the power signal line 3 and an anode of the light-emitting element D separately through the light emission control module 105. A cathode of the light-emitting element D may receive a negative power signal PVEE. In this case, when the light emission control module 105 is controlled to be turned on, a current path is formed between the positive power signal PVDD transmitted by the power signal line 3 and the negative power signal PVEE received by the cathode of the light-emitting element D so that the drive current generated by the drive module 101 according to the data signal Vdata can be supplied to the light-emitting element D and drive the light-emitting element D to emit light and perform display.

The positive power signal PVDD transmitted by the power signal line 3 is usually a fixed voltage signal. Moreover, the extension direction of the power signal line 3 is consistent with the extension direction of the data signal line 2. That is, the extension direction of the power signal line 3 and the extension direction of the data signal line 2 are each the column direction Y of the pixel units 1. Therefore, the power signal line 3 may be electrically connected to light emission control modules 105 in pixel circuits P in one or more columns to supply positive power signals PVDD to the light emission control modules 105 in the pixel circuits P in one or more columns.

It may be understood that when an applicant developed the DGLD technology, the manner in which the power signal lines and the data signal lines are alternately disposed in gaps of pixel circuits is adopted to enable signal lines in the display panel to be arranged uniformly. However, with this arrangement, a parasitic capacitance is formed between the pixel circuits and the power signal lines. At the start moment of one frame of image, at the moment when the light emission control module in a pixel circuit is controlled to be turned on, a positive power signal transmitted by a power signal line quickly charges a node electrically connected to the drive module and the light emission control module so that an instantaneously large current is generated on the power signal line. The voltage of the positive power signal on the power signal line fluctuates. The positive power signal with the instantaneously large current and fluctuating voltage is coupled into a pixel circuit through the parasitic capacitance so that the pixel circuit generates a drive current for driving a light-emitting element to emit light and perform display. Compared with a pixel circuit controlling a light-emitting element to emit light and perform display according to a received data signal, the display and light emission generated by the coupling of the positive power signal on the power signal line is abnormal display and light emission of sub-pixels. During the research process, it is found that the instantaneously abnormal light emission of sub-pixels at the start moment of one frame of image may lead to the screen flicker problem of the display panel. In order to alleviate the screen flicker problem, the applicant proposed a solution of increasing the distance between the power signal lines and reducing the pixel circuits forming a parasitic capacitance with the power signal lines.

Continuing to refer to FIG. 2, in this embodiment, the distance Ll between two adjacent power signal lines 3 is greater than or equal to the dimension of one pixel unit 1 in the row direction X. That is, at least a plurality of pixel circuits P of one pixel unit 1 are disposed between two adjacent power signal lines 3 so that other pixel circuits P and/or data signal lines 2 exist between at least part of the pixel circuits P in one pixel unit 1 and a power signal line 3. No parasitic capacitance can be formed between the power signal line 3 and the part of the pixel circuits P. In this case, at the start moment of one frame of image, a positive power signal with an instantaneously large current and fluctuating voltage transmitted by the power signal line 3 cannot be coupled to the part of the pixel circuits P so that the part of the pixels circuit P does not drive light-emitting elements D electrically connected to the pixels circuit P to emit light and perform display due to the coupling of the positive power signal PVDD transmitted by the power signal line 3. Therefore, at the start moment of one frame of image, the number of sub-pixels 1 that generate abnormal display and light emission due to the coupling action of the positive power signal PVDD transmitted by the power signal line 3 can be reduced relatively, and the abnormal display brightness of the display panel 100 is reduced to make the abnormal display brightness of the display panel 100 get not easily captured by the human eye, thus alleviating the screen flicker problem of the display panel 100 at the start moment of one frame of image and thereby improving the display effect of the display panel 100.

It may be understood that a pixel unit includes pixel circuits and light-emitting elements. Components and connection lines thereof are disposed in a pixel circuit. A light-emitting element overlaps the pixel circuit in the thickness direction of the display panel. In this case, the dimension of the pixel unit in the row direction may be the width of the arrangement region of the light-emitting elements and pixel circuits in the pixel unit in the row direction and may be the entire width of the pixel unit or the sum of the widths of sub-pixels in the pixel unit, which may be specifically designed according to actual needs and is not specifically limited in the embodiments of the present disclosure.

It needs to be noted that FIG. 2 merely exemplarily illustrates the case where the distance L1 between two adjacent power signal lines is greater than Lp and less than 2×Lp. In the embodiments of the present disclosure, the distance L1 between two adjacent power signal lines may be equal to Lp or may be greater than or equal to 2×Lp, which may be specifically designed according to actual needs and is not specifically limited in the embodiments of the present disclosure on the premise of reducing the number of pixel circuits directly adjacent to the power signal lines. Moreover, the distance L1 between two adjacent power signal lines may be a fixed value or a non-fixed value, which may be specifically designed according to actual needs and is not specifically limited in the embodiments of the present disclosure.

In an optional embodiment, the distance between two adjacent power signal lines is 2n×Lp. 1≤n≤5. n is a positive integer.

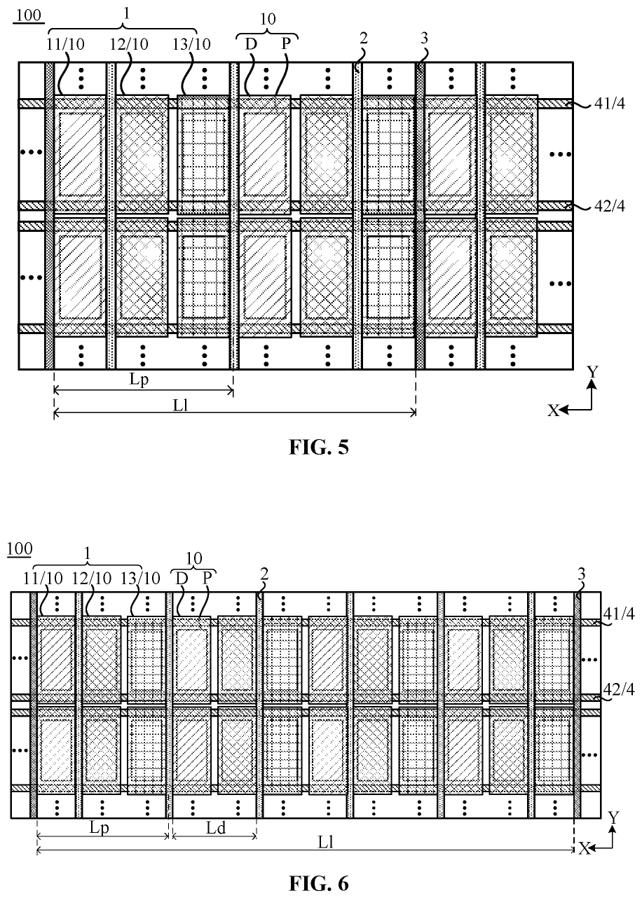

In an exemplary embodiment, as shown in FIG. 5, when n is equal to 1, Ll is equal to 2×Lp. If one pixel unit 1 includes m sub-pixels 10 arranged in the row direction, the number of sub-pixels 10 arranged in the row direction X and located between two adjacent power signal lines 3 is 2 m. Therefore, in two adjacent pixel units 1, the number of sub-pixels 10 not directly adjacent to a power signal line 3 is 2 m−2. At the start moment of one frame of image, the instantaneously large current and fluctuating voltage on the power signal line 3 cannot be coupled to the 2 m −2 sub-pixels 10 not directly adjacent to the power signal line 3. Therefore, at least 2 m −2 sub-pixels 10 in two adjacent pixel units 1 can be prevented from generating abnormal display and light emission, thus alleviating the screen flicker problem of the display panel 100 and improving the display effect of the display panel 100. Moreover, the distance L1 between each two adjacent power signal lines 3 is 2×Lp so that all the power signal lines 3 are uniformly distributed in the display panel 100, simplifying the wiring manner of the display panel 100 and improving the display uniformity of the display panel 100.

In another exemplary embodiment, as shown in FIG. 6, when n is equal to 2, Ll is equal to 4×Lp. If one pixel unit 1 includes m sub-pixels 10 arranged in the row direction, the number of sub-pixels 10 not directly adjacent to a power signal line 3 is 4m -2 in four adjacent pixel units 1. Therefore, at the start moment of one frame of image, at least the 4m −2 sub-pixels 10 in two adjacent pixel units 1 can be prevented from generating abnormal display and light emission, thus alleviating the screen flicker problem of the display panel 100 and improving the display effect of the display panel 100. Moreover, the distance L1 between each two adjacent power signal lines 3 is 4×Lp so that all the power signal lines 3 are uniformly distributed in the display panel 100, simplifying the wiring manner of the display panel 100 and improving the display uniformity of the display panel 100.

Above all, the greater the value of n, the greater the number of sub-pixels 10 located between two adjacent power signal lines 3, the greater the number of sub-pixels 10 not directly adjacent to a power signal line 3, and thus the smaller the number of sub-pixels 10 that abnormally emit light and perform display at the start moment of one frame of image. However, the pixel circuit P of a sub-pixel needs to be electrically connected to a power signal line 3. That is, the pixel circuit P located between two adjacent power signal lines 3 needs to be electrically connected to one of the two power signal lines 3. Moreover, a voltage drop in a positive power signal PVDD exists due to the transmission loss during transmission; and the longer the transmission path is, the greater the voltage drop is, thus the longer the connection distance between the pixel circuit P and the power signal line 3 is, and the lower the voltage value of the positive power signal PVDD received by the pixel circuit P is. In this case, when a relatively large difference exists between a positive power signal PVDD received by a pixel circuit P having a short connection distance and a positive power signal PVDD received by a pixel circuit P having a long connection distance, the display and light emission consistency of sub-pixels 10 to which pixel circuits P belongs may be affected, thus affecting the display uniformity of the display panel 100. On this basis, n is set to a positive integer greater than or equal to 1 and less than or equal to 5 to guarantee that a small difference exists between positive power signals PVDD received by various pixel circuits P on the premise of reducing the number of sub-pixels 10 abnormally emitting light and performing display, thus improving the display uniformity of the display panel 100.

Additionally, pixel circuits P of sub-pixels 10 in two adjacent columns are electrically connected to the same data signal line 2. The distance Ld between two adjacent data signal lines 2 may be the width, in the row direction X, of two adjacent sub-pixels 10 arranged in the row direction X. That is, in the row direction X, one data signal line 2 is provided for every two sub-pixels 10. If the number of sub-pixels 10 in a pixel unit 1 is odd, there may be sub-pixels 10 located in the same row and electrically connected to the same data signal line 2 that belong to different pixel units 1. Therefore, the arrangement in which the distance L1 between two adjacent power signal lines 3 is 2n ×Lp can guarantee that the number of sub-pixels 10 between the two adjacent power signal lines 3 is even. In this case, a data signal line 2 located between the two adjacent power signal lines 3 can be electrically connected to pixel circuits P of the sub-pixels 10 located between the two adjacent power signal lines 3, thus simplifying the wiring manner of the power signal lines 3 and the data signal lines 2, thereby simplifying the design of the display panel 100, and facilitating the low cost of the display panel 100.

It may be understood that 1≤n≤5, and n is a positive integer. That is, n may be 1, 2, 3, 4, or 5. The specific value of n may be designed according to actual needs. For ease of simplifying description and the drawings, an example in which n is 1 is taken in all the embodiments of the present disclosure to practically explain the technical solutions of the embodiments of the present disclosure without special limitation.

It may also be understood that a positive power signal PVDD transmitted by a power signal line 3 is a fixed voltage signal. Therefore, light emission control modules in pixel circuits P in the same row may be simultaneously turned on to simultaneously write the positive power signal PVDD into the pixel circuits P. In this case, the number of pixel circuits P connected to the power signal line 3 may be a fixed value or a non-fixed value. That is, the number of pixel circuits P connected to two adjacent power signal lines 3 may be the same or may be different, which may be specifically designed according to actual needs and is not specifically limited in the embodiments of the present disclosure.

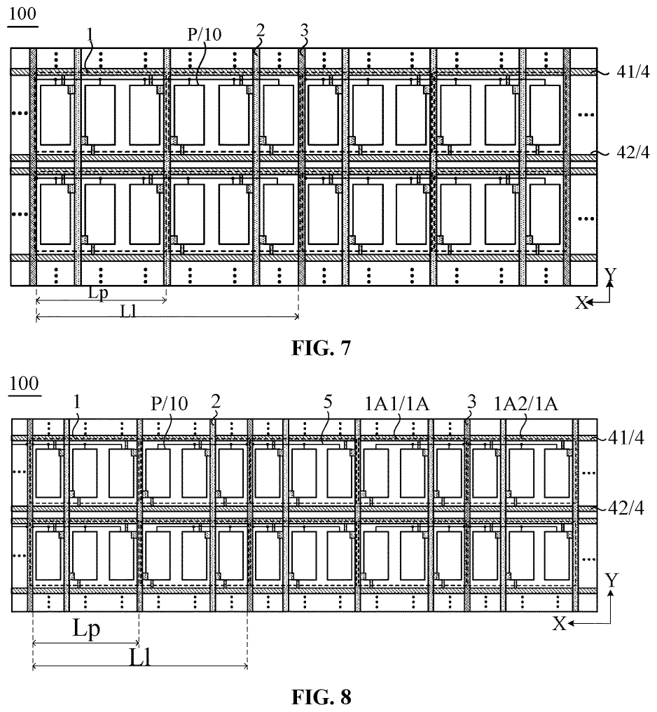

In an optional embodiment, as shown in FIG. 7, a power signal line 3 is electrically connected to pixel circuits P in 2n pixel units 1 arranged in the row direction X. n is a positive integer.

The pixel circuits P of the 2n pixel units 1 arranged in the row direction X share one power signal line 3 so that it is not necessary to provide a power signal line 3 for each pixel unit 1 separately, reducing the number of power signal lines, reducing the occupied space of the power signal lines 3, relatively increasing the arrangement space of the pixel circuits P, thereby improving the resolution of the display panel 100. Moreover, the power signal line 3 is electrically connected to the pixel circuits P in the 2n pixel units 1 arranged in the row direction X. When the number of pixel circuits P in each pixel unit 1 is constant, the number of pixel circuits P electrically connected to the power signal line 3 may be fixed so that the number of pixel circuits P electrically connected to each power signal line 3 is consistent. In this case, the amount of load on each power supply signal line 3 may keep consistent, and a positive power signal PVDD supplied by each power signal line 3 to pixel circuits P may keep consistent, thereby improving the display uniformity of the display panel 100.

Additionally, the number of power signal lines 3 is electrically connected to pixel circuits P in the 2n pixel units 1 arranged in the row direction X, that is, the number of pixel circuits P located in the same row and electrically connected to the same power signal line 3, are even. Pixel circuits P of two adjacent sub-pixels 10 arranged in the row direction X are electrically connected to the same data signal line 2 so that among an even number of pixel circuits P located in the same row and electrically connected to the same power signal line 3, every two pixel circuits P may be electrically connected to one data signal line 2. Therefore, pixel circuits P electrically connected to the same data signal line 2 may be electrically connected to the same power signal line 3, improving the consistency of positive power signals PVDD and data signals Vdata received by various pixel circuits P and thereby improving the display uniformity of the display panel 100.

It may be understood that the pixel circuits P of the 2n pixel units 1 arranged in the row direction X are electrically connected to the same power signal line 3. The 2n pixel units arranged in the row direction X may be located on the same side of the power signal line 3 or two opposite sides of the power signal line 3, which may be specifically designed according to actual needs and is not specifically limited in the embodiments of the present disclosure.

In an optional embodiment, as shown in FIG. 8, n adjacent pixel units 1 arranged in the row direction X constitute a pixel unit group 1A. A power signal line 3 is electrically connected to pixel circuits P in two pixel unit groups 1A (1A1 and 1A2) at two opposite sides of the power signal line 3 separately.

The power signal line 3 may be electrically connected to the two pixel unit groups 1A. The two pixel unit groups 1A are located at two opposite sides of the power signal line 3. For example, the power signal line 3 may be electrically connected to a pixel unit group 1A1 at the left side of the power signal line 3 and a pixel unit group 1A2 at the right side of the power signal line 3 so that the transmission paths of positive power signals PVDD received by the pixel circuits P in the two pixel unit groups 1A located at two opposite sides of the power signal line 3 are consistent, thereby improving the consistency of the positive power signals PVDD received by the pixel circuits P and thereby improving the display uniformity of the display panel 100.

It may be understood that the power signal line 3 is electrically connected to the pixel unit groups 1A at two opposite sides of the power signal line 3. That is, a pixel unit group 1A electrically connected to the power signal line 3 may be a pixel unit group 1A adjacent to the power signal line 3 or not adjacent to the power signal line 3, which may be specifically designed according to actual needs and is not specifically limited in the embodiments of the present disclosure.

In an optional embodiment, continuing to refer to FIG. 8, the power signal line 3 is located at a gap between two adjacent pixel unit groups 1A arranged in the row direction X. That is, the power signal line 3 may be located at a gap between the two pixel unit groups 1A electrically connected to the power signal line 3 so that the pixel unit groups 1A can be adjacent to the power signal line 3 electrically connected to the pixel unit groups 1A, thus guaranteeing that the transmission paths of the positive power signals PVDD supplied by the power signal line 3 to the pixel circuits P in the pixel unit groups 1A are relatively short, improving the accuracy of the positive power signals PVDD received by the pixel circuits P, thereby improving the display and light emission accuracy of light-emitting elements electrically connected to the pixel circuits P, and improving the display effect of the display panel 100.

Additionally, the arrangement in which the power signal line 3 is disposed at a gap between the two adjacent pixel unit groups 1A arranged in the row direction X enables two adjacent power signal lines 3 can be uniformly arranged in the display panel 100, simplifying the wiring manner of the display panel 100, reducing the design cost of the display panel 100, and helping with the low cost of the display panel 100.

It needs to be noted that the connection manner between the power signal lines 3 and the pixel circuits P in the pixel units 1 is merely exemplarily described above. The connection manner between the power signal lines 3 and the pixel circuits P may be designed according to actual needs and is not specifically limited in the embodiments of the present disclosure on the premise that the core inventive point of the embodiments of the present disclosure can be implemented. For ease of simplifying description and the drawings, without special limitation, an example in which a power signal line 3 is located at a gap between two pixel unit groups 1A electrically connected to the power signal line 3 and located in the same row is taken in the embodiments of the present disclosure to exemplarily describe at least part of the technical solutions in the embodiments of the present disclosure.

On the basis of the preceding embodiments, optionally, continuing to refer to FIG. 8, the display panel 100 may further include a plurality of power connection lines 5 extending in the row direction X. A power signal line 3 is connected to a pixel circuit P through a power connection line 5.

Among at least part of the pixel circuits P electrically connected to the power signal line 3, at least one other pixel circuit P is disposed between a pixel circuit P and the power signal line 3. In order to implement the connection between the pixel circuit P and the power signal line 3, the power connection line 5 needs to be provided so as to connect the power signal line 3 to the pixel circuit P. The power connection lines 5 may extend in the row direction X so that multiple adjacent pixel circuits P located in the row direction X may be electrically connected to a power signal line 3 through the same power connection line 5, simplifying the wiring manner of the power connection lines 5.

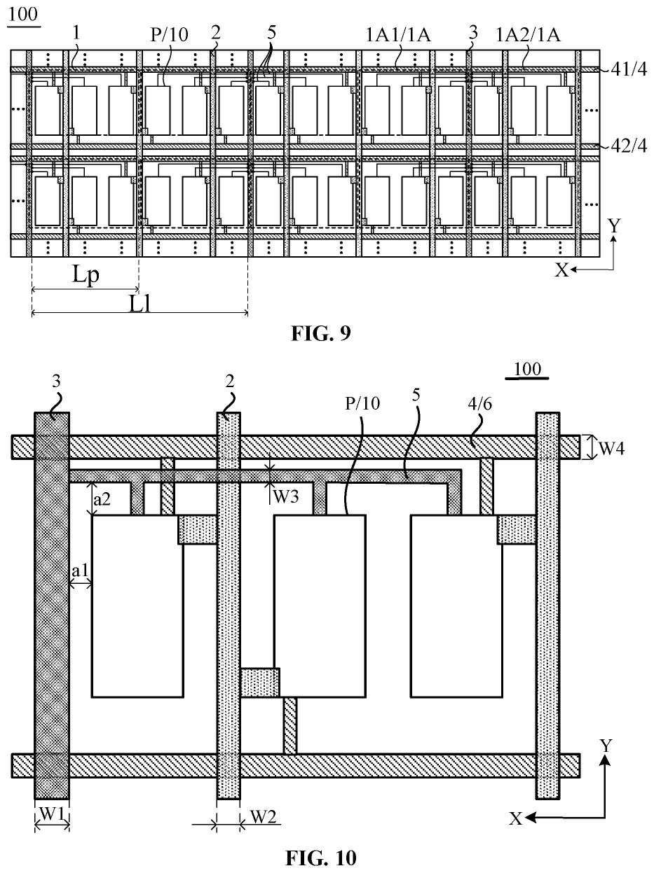

In other optional embodiments, as shown in FIG. 9, pixel circuits P arranged in the row direction X may also be electrically connected to the same power signal line 3 through different power connection lines 5. In this case, the pixel circuits P arranged in the row direction X may receive positive power signals PVDD transmitted by the power signal line 3 through different power connection lines 5, respectively, so that each power connection line 5 has a low load, improving the transmission accuracy of the positive power signals PVDD on the power connection lines 5, improving the accuracy of the positive power signals PVDD received by the pixel circuits P, thus improving the display and light emission accuracy of light-emitting elements electrically connected to the pixel circuits P, and improving the display effect of the display panel 100.

It needs to be noted that the specific connection relationship between the power connection lines 5 and the pixel circuits P may be designed according to actual needs and is not specifically limited in the embodiments of the present disclosure. For ease of description, without special limitation, an example in which multiple adjacent pixel circuits P located in the row direction X are electrically connected to a power signal line 3 through the same power connection line 5 is taken in the embodiments of the present disclosure to exemplarily describe the technical solutions in the embodiments of the present disclosure.

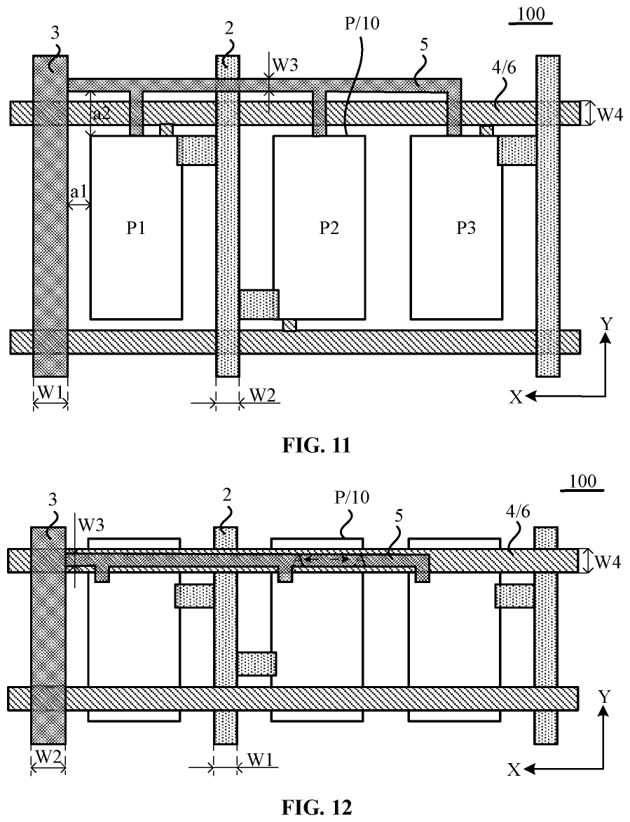

In an optional embodiment, FIG. 10 is an enlarged view illustrating the partial structure of a display panel according to an embodiment of the present disclosure. As shown in FIG. 10, the line width of a power connection line 5 in the column direction Y is W3. The line width of a power signal line 3 in the row direction X is W1. W1>W3

The power connection line 5 extends in the row direction X to be electrically connected to pixel circuits P arranged in the row direction X separately. The power signal line 3 extends in the column direction Y to be electrically connected to pixel circuits P arranged in the column direction Y and the power connection line 5 arranged in the column direction Y separately. In this case, the same power signal line 3 can be electrically connected to pixel circuits P in multiple columns. Therefore, the power signal line 3 serves as a backbone transmission line of a positive power signal PVDD, and the power connection line 5 serves as a branch transmission line of the positive power signal PVDD. The line width W1 of the power signal line 3 in the row direction X is set to be greater than the line width of the power connection line 5 in the column direction Y so that the power signal line 3 per unit length has low impedance, thus guaranteeing the transmission accuracy of the positive power signal PVDD in the backbone transmission line. Moreover, the power connection line 5 extends in the row direction X so that the power connection line 5 overlaps each pixel circuit P electrically connected to the power connection line 5 in the column direction Y. Moreover, when the power connection line 5 is directly adjacent to a pixel circuit P electrically connected to the power connection line 5, a parasitic capacitance is formed between the power connection line 5 and the directly adjacent pixel circuit P. However, due to the relatively small width of the power connection line 5, the parasitic capacitance formed between the power connection line 5 and the pixel circuit P is relatively small, resulting in a relatively small amount of signals coupled to the pixel circuit P from the power connection line 5. Therefore, the instantaneously large current and fluctuating voltage of the positive power signal PVDD on the power connection line 5 may not affect the pixel circuit P to drive a respective light-emitting element to emit light and perform display, guaranteeing the display and light emission effect of the display panel 100.

Additionally, when the power connection line 5 is arranged at a gap between pixel circuits P in two adjacent rows, the arrangement in which the power connection line 5 has a relatively small line width W3 in the column direction Y enables the power connection line 5 to occupy a relatively small space in the column direction Y and relatively increases the gap size between the power connection line 5 and the pixel circuits P so as to reduce the parasitic capacitance formed between the power connection line 5 and the pixel circuits P, thus reducing the amount of signal coupling of positive power signals PVDD with instantaneously large currents and fluctuating voltages from the power connection line 5 to the pixel circuits P, thereby guaranteeing that the pixel circuits P drive light-emitting elements electrically connected to the pixel circuits P to emit light accurately, and improving the display effect of the display panel 100.

Optionally, continuing to refer to FIG. 10, in the power signal line 3 and the power connection line 5 connected to each other, the distance between the power signal line 3 and a pixel circuit P closest to the power signal line 3 in the row direction X is a1, and the distance between the power connection line 5 and a pixel circuit P closest to the power connection line 5 in the row direction is a2. a2>a1

The arrangement in which a2>a1 enables the distance between the power connection line 5 and the pixel circuit P closest to the power connection line 5 to be relatively long so as to reduce the parasitic capacitance formed by the power connection line 5 and the pixel circuit P closest to the power connection line 5, thus reducing the amount of signal coupling of a positive power signal PVDD with an instantaneously large current and fluctuating voltage from the power connection line 5 to the pixel circuit P, thereby guaranteeing that the pixel circuit P drives a light-emitting element electrically connected to the pixel circuit P to emit light accurately, and improving the display effect of the display panel 100.

Additionally, the distance between the power signal line 3 and the pixel circuit P closest to the power signal line 3 is relatively short, reducing the gap size between the power signal line 3 and the pixel circuit P, relatively increasing the occupied space of the power signal line 3, guaranteeing a relatively great line width of the power signal line 3, and reducing the transmission impedance of the positive power signal PVDD transmitted by the power signal line 3, improving the accuracy of the positive power signal PVDD received by the pixel circuit P, thus improving the light emission accuracy of the light-emitting element driven by the pixel circuit P, and thereby improving the display effect of the display panel 100.

It needs to be noted that the case where the power connection line 5 is adjacent to the pixel circuit P so that the parasitic capacitance is formed between the power connection line 5 and the pixel circuit P is merely exemplified above. In the embodiments of the present disclosure, other structures may be disposed between the power connection line 5 and the pixel circuit P so that no parasitic capacitance can be directly formed between the power connection line 5 and the pixel circuit P. Another structure disposed between the power connection line 5 and the pixel circuit P may be a shielding structure disposed separately in the display panel 100 or an existing structure in the display panel 100 that is multiplexed, which may be specifically designed according to actual needs and is not specifically limited in the embodiments of the present disclosure.

Optionally, as shown in FIG. 11, the display panel 100 may further include a plurality of first signal lines 6 extending in the row direction X and arranged in the column direction Y. At least part of the pixel circuits P located in the same row are electrically connected to the same first signal line 6. At least one first signal line 6 is disposed between a power connection line 5 and a pixel circuit P.

A first signal line 6 may be used for transmitting a fixed voltage signal or an alternating voltage signal and may be specifically designed according to actual needs. The signal transmitted by the first signal line 6 is a signal required for normal operation of a pixel circuit P.

It may be understood that at the start moment of one frame of image, the signal transmitted by the first signal line 6 does not generate a large instantaneously current so that the signal transmitted by the first signal line 6 is not coupled to the pixel circuit P. Alternatively, the signal amount of signals transmitted by the first signal line 6 and coupled to the pixel circuit P is relatively small, thus guaranteeing that a parasitic capacitance formed between the first signal line 6 and the pixel circuit P does not affect the magnitude of the drive current provided by the pixel circuit P to a respective light-emitting element, thus guaranteeing the display and light emission accuracy of the light-emitting element driven by the pixel circuit P.

Moreover, the power connection line 5 is used for electrically connecting the pixel circuit P to a power signal line 3 so that a signal transmitted by the power connection line 5 is consistent with a signal transmitted by the power signal line 3. That is, the signal transmitted by the power connection line 5 will vary with the signal transmitted by the power signal line 3. That is, when a positive power signal PVDD transmitted by the power signal line 3 has an instantaneously large current and fluctuating voltage, a positive power signal PVDD transmitted by the power connection line 5 also has an instantaneously large current and fluctuating voltage. The arrangement in which the first signal line 6 is disposed between the power connection line 5 and the pixel circuit P can enable the first signal line 6 to serve as an isolation structure between the power connection line 5 and the pixel circuit P so that no parasitic capacitance can be directly formed between the power connection line 5 and the pixel circuit P, thereby preventing the positive power signal PVDD on the power connection line 5 from being coupled to the pixel circuit P and affecting the display and light emission accuracy of the light-emitting element driven by the pixel circuit P. In this case, the arrangement in which the first signal line 6 is disposed between the power connection line 5 and the pixel circuit P can alleviate the case where the instantaneously large current and fluctuating voltage of the positive power signal PVDD cause the light-emitting element to abnormally emit light and perform display, thus improving the display effect of the display panel 100.

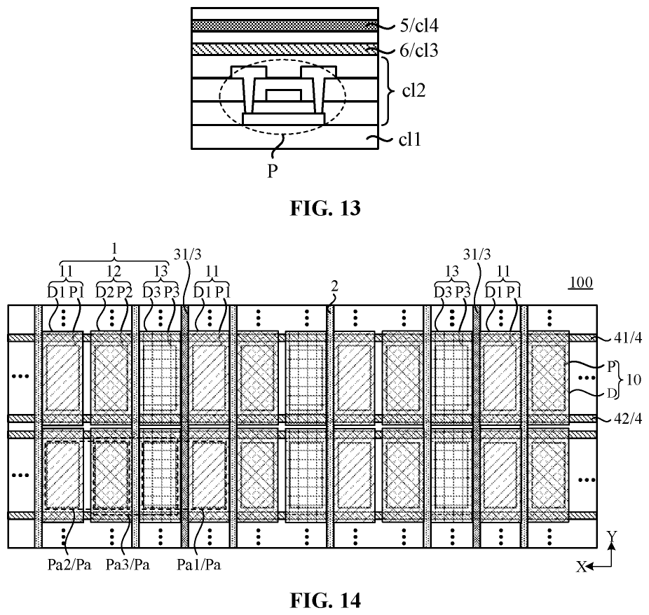

The arrangement in which the first signal line 6 is located between the power connection line 5 and the pixel circuit P may be understood as that in a direction parallel to the plane where the display panel 100 is located, the power connection line 5 is located on a side of the first signal line 6 facing away from the pixel circuit P (as shown in FIG. 11) or that in the thickness direction of the display panel 100, a layer where the power connection line 5 is located is located on a side of a layer where the first signal line 6 is located facing away from a layer where the pixel circuit P is located (as shown in FIGS. 12 and 13). On the premise that the first signal line 6 can be used for isolating the power connection line 5 from the pixel circuit P, this is not specifically limited in the embodiments of the present disclosure.

In an exemplary embodiment, referring to FIGS. 12 and 13, by way of example, one transistor represents a pixel circuit P. The display panel 100 includes a base substrate cl1, a circuit disposition layer cl2 located on one side of the base substrate cl1, a first signal line layer cl3 located on one side of the circuit disposition layer cl2 facing away from the base substrate cl1, and a second signal line layer cl4 located on one side of the first signal line layer cl3 facing away from the base substrate cl1. The circuit disposition layer cl2 is provided with the pixel circuit P. The first signal line layer cl3 is provided with the first signal line 6. The second signal line layer cl4 is provided with the power connection line 5. The power connection line 5 overlaps the first signal line 6 in a direction perpendicular to the plane where the base substrate cl1 is located. Moreover, the power connection line 5 and the first signal line 6 may both extend in the row direction X. That is, the extension direction of the power connection line 5 is the same as the extension direction of the first signal line 6. The line width W4 of the first signal line 6 in the column direction Y may be greater than the line width W3 of the power connection line 5 in the column direction Y so that the first signal line 6 can completely isolate the power connection line 5 extending in the row direction X from the pixel circuit P. In this case, the first signal line layer cl3 is located between the circuit disposition layer cl2 and the second signal line layer cl4 so that the first signal line 6 in the first signal line layer cl3 can isolate the pixel circuit P in the circuit disposition layer cl2 from the power connection line 5 in the second signal line layer cl4, preventing the positive power signal PVDD transmitted by the power connection line 5 from being coupled to the pixel circuit P, thus guaranteeing the display and light emission accuracy of the light-emitting element driven by the pixel P, and enabling the display panel 100 to have a high display quality.

It needs to be noted that the layer structure of the display panel is merely exemplified above. In the embodiments of the present disclosure, the layer structure of the display panel is not limited thereto, which may be specifically designed according to actual needs and is not specifically limited in the embodiments of the present disclosure.

It may be understood that the first signal line is electrically connected to the pixel circuit. The first signal line may transmit a signal required by the pixel circuit. In an exemplary embodiment, referring to FIG. 11 or 12, when the display panel 100 includes a first gate signal line 4 electrically connected to the data write module in the pixel circuit P, the first signal line 6 may serve as the first gate signal line 4 so that the first gate signal line can isolate the pixel circuit P from the power connection line. In other exemplary embodiments, the first signal line may serve as another signal line electrically connected to the pixel circuit P, which may be specifically designed according to the structure of the pixel circuit P and the required signal.

In an exemplary embodiment, referring to FIG. 3, the pixel circuit P includes a drive module 101, a data write module 102, a reset module 103, a threshold compensation module 104, a light emission control module 105, an initialization module 106, and a storage capacitor Cst. The drive module 101 may include a drive transistor M1. The data write module 102 may include a data write transistor M2. A first electrode of the data write transistor M2 may receive a data signal Vdata transmitted by a data signal line. A second electrode of the data write transistor M2 may be electrically connected to a first electrode of the drive transistor M1. A gate of the data write transistor M2 may receive a first gate signal S2 so that the first gate signal S2 may control the data write transistor M2 to be turned on or off. The threshold compensation module 104 may include a threshold compensation transistor M4. A first electrode of the threshold compensation transistor M4 may be electrically connected to a second electrode of the drive transistor M1. A second electrode of the threshold compensation transistor M4 may be electrically connected to a gate of the drive transistor M1. A gate of the threshold compensation transistor M4 may receive the first gate signal S2 so that the first gate signal S2 may control the threshold compensation transistor M4 to be turned on or off. The reset module 103 may include a reset transistor M3. A first electrode of the reset transistor M3 may receive a reset signal Vref1. A second electrode of the reset transistor M3 may be electrically connected to the gate of the drive transistor M1. A gate of the reset transistor M3 may receive a second gate signal S1 so that the second gate signal S3 may control the reset transistor M3 to be turned on or off. The light emission control module 105 may include a first light emission control transistor M5 and a second light emission control transistor M6. A first electrode of the first light emission control transistor M5 receives a positive power signal PVDD transmitted by a power signal line. A second electrode of the first light emission control transistor M5 is electrically connected to the first electrode of the drive transistor M1. The second electrode of the data write transistor M2 is electrically connected to the second light emission control transistor M6. A second electrode of the second light emission control transistor M6 is electrically connected to an anode of a light-emitting element D. A cathode of the light-emitting element D may receive a negative power signal PVEE. A gate of the first light emission control transistor M5 and a gate of the second light emission control transistor M6 both receive a light emission control signal EM so that the light emission control signal EM may control the first light emission control transistor M5 and the second light emission control transistor M6 to be turned on or off. The initialization module 106 includes an initialization transistor M7. A first electrode of the initialization transistor M7 may receive an initialization signal Vref2. A second electrode of the initialization transistor M7 may be electrically connected to the anode of the light-emitting element D. A gate of the initialization transistor M7 may receive a third gate signal S3 so that the third gate signal S3 may control the initialization transistor M7 to be turned on or off. A first plate of the storage capacitor Cst may receive the positive power signal PVDD transmitted by the power signal line. A second plate of the storage capacitor Cst is electrically connected to the gate of the drive transistor M1.

When the second gate signal S1 controls the reset transistor M3 to be turned on, the reset transistor M3 may transmit the reset signal Vref2 to the gate of the drive transistor M1 to reset the gate of the drive transistor M1 and the storage capacitor Cst. When the first gate signal S2 controls the data write transistor M2 and the threshold compensation transistor M4 to be turned on, the data signal Vdata transmitted by the data signal line and the threshold voltage of the drive transistor M1 are both written to the gate of the drive transistor M1 and stored in the storage capacitor Cst. When the third gate signal S3 controls the initialization transistor M7 to be turned on, the initialization transistor M7 may supply the initialization signal Vref2 to the anode of the light-emitting element D to initialize the light-emitting element D. When the light emission control signal EM controls the first light emission control transistor M5 and the second light emission control transistor M6 to be turned on, a current path in a conduction state is formed from the positive power signal PVEE to the negative power signal PVEE so that a drive current generated by the drive transistor M1 according to a gate signal of the drive transistor M1 is supplied to the light-emitting element D and drive the light-emitting element D to emit light and perform display.

Accordingly, the display panel 100 may further include a reset signal line, an initialization signal line, a first gate signal line, a second gate signal line, a third gate signal line, and a light emission control line. The reset signal line is used for transmitting the reset signal Vref1. The initialization signal line is used for transmitting the initialization signal Vref2. The first gate signal line is used for transmitting the first gate signal S2. The second gate signal line is used for transmitting the second gate signal S2. The third gate signal line is used for transmitting the third gate signal S3. The light emission control line is used for transmitting the light emission control signal EM. In this case, the first signal line may be at least one of a reset signal line, an initialization signal line, a first gate signal line, a second gate signal line, a third gate signal line, or a light emission control line. With this arrangement, no additional structure for isolating the power connection line from the pixel circuit P needs to be provided, simplifying the structure of the display panel and reducing the cost of the display panel.

It needs to be noted that the structure of the pixel circuit in the display panel in the embodiments of the present disclosure is merely exemplified above. The structure of the pixel circuit in the embodiments of the present disclosure is not limited thereto and may be specifically designed according to actual needs. For ease of description, without special limitation, an example of the structure of the pixel circuit shown in FIG. 3 is taken in the embodiments of the present disclosure to exemplarily describe the technical solutions in the embodiments of the present disclosure.

It may be understood that a pixel unit in the display panel includes a plurality of sub-pixels of different colors. Light-emitting elements in the sub-pixels of different colors have different emission colors. Since the sensitivity of the human eye to the light of different colors is different, the brightness visual sensitivity of the light emitted from the sub-pixels of different colors is different. Therefore, at the start moment of one frame of image, in the abnormal display and light emission caused by an instantaneously large current and fluctuating voltage of a positive power signal, the color of light is a color with low visual sensitivity of the human eye and is more difficult to be seen by the human eye. Therefore, when a power signal line is provided, it is possible to make the power signal line be as close as possible to a sub-pixel whose emitted light has a color of low visual sensitivity to the human eye and be far away from a sub-pixel having a color of high visual sensitivity to the human eye.

In an optional embodiment, as shown in FIG. 14, the pixel units 1 include first sub-pixels 11, second sub-pixels 12, and third sub-pixels 13 arranged in the row direction X. A first pixel circuit P1 is a pixel circuit of a first sub-pixel 11. A second pixel circuit P2 is a pixel circuit of a second sub-pixel 12. A third pixel circuit P3 is a pixel circuit of a third sub-pixel 13. The emission wavelength of the first sub-pixel 11 is greater than the emission wavelength of the second sub-pixel 12. The emission wavelength of the second sub-pixel 12 is greater than the emission wavelength of the third sub-pixel 13. Two adjacent pixel circuits P arranged in the row direction X constitute a sub-display group Pa. Sub-display groups Pa include first sub-display groups Pa1. Two pixel circuits P in a first sub-display group Pa1 are a first pixel circuit P1 and a third pixel circuit P3. The plurality of power signal lines 3 include a first power signal line 31 located at a gap between the two adjacent pixel circuits P in the first sub-display group Pa1.

The emission wavelength of the first sub-pixel 11 is greater than the emission wavelength of the second sub-pixel 12. The emission wavelength of the second sub-pixel 12 is greater than the emission wavelength of the third sub-pixel 13. In this case, the emission color of the first sub-pixel 11 may be red, the emission color of the second sub-pixel 12 may be green, and the emission color of the third sub-pixel 13 may be blue. In the display panel 100, when only the first sub-pixels 11 and the second sub-pixels 12 emit light, the color of a display image of the display panel 100 tends to be yellow. When only the second sub-pixels 12 and the third sub-pixels 13 emit light, the color of a display image of the display panel 100 tends to be cyan. When only the first sub-pixels 11 and the third sub-pixels 13 emit light, the color of a display image of the display panel 100 tends to be purple.

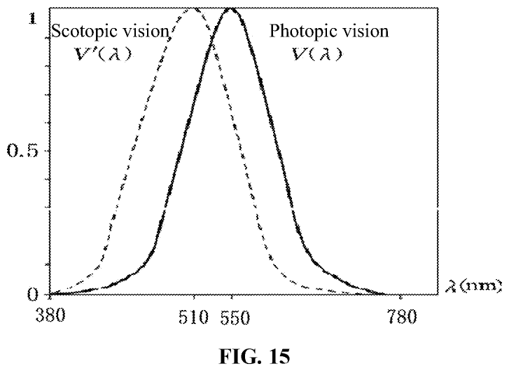

It may be understood that in the photopic and scotopic vision, the human eye has different sensitivity to light of different colors. As shown in FIG. 15, the abscissa represents the wavelength of light, and the ordinate represents the normalized visual perception brightness. It may be seen from FIG. 15 that in the photopic vision, the visual perception brightness V(λ) of the human eye reaches its peak when the wavelength of light is 550 nm. In the scotopic vision, the visual perception brightness V'(λ) of the human eye reaches its peak when the wavelength of light is 510 nm. The wavelength of yellow light is 580 nm. The wavelength of purple light is 460 nm. The wavelength of cyan light is 490 nm. Therefore, the human eye has low visual sensitivity to purple light and high visual sensitivity to yellow light and erotic light.

Continuing to refer to FIG. 14, two pixel circuits P in a first sub-display group Pa1 are a first pixel circuit P1 and a third pixel circuit P3. A sub-pixel to which the first pixel circuit P1 belongs is a first sub-pixel 11 whose emission color is red. A sub-pixel to which the third pixel circuit P3 belongs is a third sub-pixel 13 whose emission color is blue. A first power signal line 31 is disposed at a gap between two adjacent pixel circuits P (P1 and P3) in the first sub-display group Pa1 so that at the start moment of one frame of image, a positive power signal PVDD with an instantaneously large current and fluctuating voltage on the first power signal line 31 is coupled to the first pixel circuit P1 and the third pixel circuit P3 adjacent to the first power signal line 31. In this case, the first sub-pixel 11 to which the first pixel circuit P1 belongs and the third sub-pixel 13 to which the third pixel circuit P3 belongs emit light and perform display simultaneously. When only the first power signal line 31 is disposed in the display panel 100, the display and light emission caused by the coupling action of the positive power signal PVDD with the instantaneously large current and fluctuating voltage may make a display image of the display panel 100 tend to be purple. That is, the color of the display image presented by the display panel 100 tends to be a color with low visual sensitivity of the human eye. In this case, the instantaneous display image of the display panel 100 is less easily perceived by the human eye, thus alleviating the screen flicker problem of the display panel 100 and improving the display effect of the display panel 100.

It may be understood that when sub-pixels arranged in the row direction and included in the pixel units 1 include the first sub-pixels 11, the second sub-pixels 12, and the third sub-pixels 13, two pixel circuits P in the same sub-display group Pa may belong to the same pixel unit 1 or may belong to different pixel units 1. For example, in the same pixel unit 1, when a first sub-pixel 11, a second sub-pixel 12, and a third sub-pixel 13 are sequentially arranged in the row direction, the two pixel circuits P in the first sub-display group Pa1 belong to two adjacent pixel units 1, respectively. Accordingly, the sub-display groups Pa may further include second sub-display groups Pa2 and third sub-display groups Pa3. Two pixel circuits P arranged in the row direction X in a second sub-display group Pa2 are a first pixel circuit P1 and a second pixel circuit P2. Two pixel circuits P arranged in the row direction X in a third sub-display group Pa3 are a second pixel circuit P2 and a third pixel circuit P3. The two pixel circuits P in the second sub-display group Pa2 may belong to the same pixel unit 1. The two pixel circuits P in the third sub-display group Pa3 may also belong to the same pixel unit 1. With this arrangement, any two adjacent pixel circuits P may constitute one sub-display group Pa so that the second pixel circuit P2 in the second sub-display group Pa2 may also be the second pixel circuit P2 in the third sub-display group Pa3, the third pixel circuit P3 in the third sub-display group Pa3 may also be the third pixel circuit P3 in the first sub-display group Pa1, and the first pixel circuit P1 in the first sub-display group Pa1 may also be the first pixel circuit P1 in the second sub-display group Pa2.

It needs to be noted that the case where a power signal line is disposed merely at the gap between the two adjacent pixel circuits in the first sub-display group is described above. The arrangement manner of a power signal line is not limited thereto. That is, a power supply signal line may also be disposed at a gap between two adjacent pixel circuits in the second sub-display group and/or the third sub-display group, which may be specifically designed according to actual needs and is not specifically limited in the embodiments of the present disclosure.

In an optional embodiment, the sub-display groups Pa include the first sub-display groups Pa1, the second sub-display groups Pa2, and the third sub-display groups Pa3. Two pixel circuits P in a first sub-display group Pa are a first pixel circuit P1 and a third pixel circuit P3. Two pixel circuits P in a second sub-display group Pa2 are a first pixel circuit P1 and a second pixel circuit P2. Two pixel circuits P in a third sub-display group Pa3 are a second pixel circuit P2 and a third pixel circuit P3. In this case, the plurality of power signal lines 3 may include first power signal lines 31, second power signal lines 32, and third power signal lines 33. A first power signal line 31 is located at a gap between two adjacent pixel circuits P (P1 and P3) in the first sub-display group Pa1. A second power signal line 32 is located at a gap between two adjacent pixel circuits P (P1 and P2) in the second sub-display group Pa2. A third power signal line 33 is located at a gap between two adjacent pixel circuits P (P2 and P3) in the third sub-display group Pa3.

At the start moment of one frame of image, a positive power signal PVDD with an instantaneously large current and fluctuating voltage transmitted by the first power signal line 31 is coupled to the first pixel circuit P1 and the third pixel circuit P3 that are adjacent to the first power signal line 31 so that a first sub-pixel 11 to which the first pixel circuit P1 belongs and a third sub-pixel 13 to which the third pixel circuit P3 belongs emit light and perform display simultaneously. A positive power signal PVDD with an instantaneously large current and fluctuating voltage transmitted by the second power signal line 32 is coupled to the first pixel circuit P1 and the second pixel circuit P2 that are adjacent to the second power supply signal line 32 so that a first sub-pixel 11 to which the first pixel circuit P1 belongs and a second sub-pixel 12 to which the second pixel circuit P2 belongs emit light and perform display simultaneously. A positive power signal PVDD with an instantaneously large current and fluctuating voltage transmitted by the third power signal line 33 is coupled to the second pixel circuit P2 and the third pixel circuit P3 that are adjacent to the third power signal line 33 so that a second sub-pixel 12 to which the second pixel circuit P2 belongs and a third sub-pixel 13 to which the third pixel circuit P3 belongs emit light and perform display simultaneously. With this arrangement, when the first power signal lines 31, the second power signal lines 32, and the third power signal lines 33 are all disposed in the display panel 100, the display and light emission caused by the coupling action of each positive power signal PVDD of an instantaneously large current and fluctuating voltage causes the first sub-pixels 11, the second sub-pixels 12, and the third sub-pixels 13 to exist in the display panel 100. When the display brightness of the first sub-pixels 11, the second sub-pixels 12, and the third sub-pixels 13 is consistent, a combination of emission colors of the first sub-pixels 11, the second sub-pixels 12, and the third sub-pixels 13 may make the overall display color of the display panel 100 tend to be white, improving the overall display color cast of the display panel 100, thus making the instantaneous display and light emission of the display panel 100 less easily perceived by the human eye in a bright environment, thereby alleviating the screen flicker problem of the display panel 100, and improving the display effect of the display panel 100.

It may be understood that the distance Ll between two adjacent power signal lines 3 is greater than Lp. Therefore, when the power signal lines 3 include the first power signal lines 31, the second power signal lines 32, and the third power signal lines 33, it can still guarantee that a small number of sub-pixels that abnormally emit light and perform display exist in the display panel 100, thus alleviating the screen flicker problem of the display panel 100 and improving the display effect of the display panel 100.

Additionally, when the power signal lines 3 include the first power signal lines 31, the second power signal lines 32, and the third power signal lines 33, the number of first power signal lines 31, the number of second power signal lines 32, and the number of third power signal lines 33 may be the same or different, which may be specifically designed according to actual needs and is not specifically limited in the embodiments of the present disclosure.

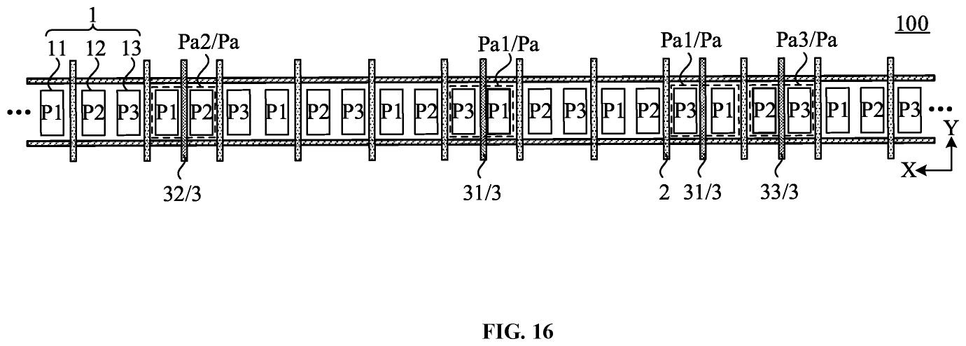

In an optional embodiment, continuing to refer to FIG. 16, among the plurality of power signal lines 3, the number of first power signal lines 31 is greater than the number of second power signal lines 32, and the number of first power signal lines 31 is greater than the number of third power signal lines 33.

The number of first power signal lines 31 is greater than both the number of second power signal lines 32 and the number of third power signal lines 33. This may be understood as that the entire number of first power signal lines 31 in the display panel 100 is greater than the entire number of second power signal lines 32 and greater than the entire number of third power signal lines 33. In an optional embodiment, at least one first display region may exist in the display panel 100. In a first display region, the arrangement density of first power signal lines 31 is greater than the arrangement density of second power signal lines 32 and the arrangement density of third power signal lines 33. For example, k11 first power signal lines 31, k21 second power signal lines 32, and k31 third power signal lines 33 are disposed in the first display region. k11>k21. k11>k31. k11, k21, and k31 are each a natural number. In other optional embodiments, at least one first second display region may exist in the display panel 100. The number of first display regions may be greater than the number of second display regions. In a second display region, the arrangement density of first power signal lines 31 may be less than or equal to the arrangement density of second power signal lines 32 and/or the arrangement density of third power signal lines 33. For example, k12 first power signal lines 31, k22 second power signal lines 32, and k33 third power signal lines 33 are disposed in the second display region. k12≤k22. k12≤k32. k12, k22, and k32 are each a natural number. On the premise that the number of first power signal lines 31 is guaranteed to be greater than both the number of second power signal lines 32 and the number of third power signal lines 33, the specific arrangement manner of the first power signal lines 31, the second power signal lines 32, and the third power signal lines 33 is not limited in the embodiments of the present disclosure.

Accordingly, with the arrangement in which the number of first power signal lines 31 is greater than both the number of second power signal lines 32 and the number of third power signal lines 33, the number of first sub-display groups Pa1 provided with the first power signal lines 31 is relatively great, and the number of second sub-display groups Pa2 provided with the second power signal lines 32 and the number of third sub-display groups Pa3 provided with the third power signal lines 33 are both relatively little. In this case, at the start moment of one frame of image, in the abnormal display and light emission caused by the instantaneously large current and fluctuating voltage of a positive power signal PVDD, the amount of purple light is relatively great, and the amount of yellow light and the amount of cyan light are relatively small.

Moreover, in a first sub-display group Pa1, when a first sub-pixel 11 to which a first pixel circuit P1 belongs and a third sub-pixel 13 to which a third pixel circuit P3 belongs emit light and perform display simultaneously, the presented emitted light is purple. In a second sub-display group Pa2, when a first sub-pixel 11 to which a first pixel circuit P1 belongs and a second sub-pixel 12 to which a second pixel circuit P2 belongs emit light and perform display simultaneously, the presented emitted light is yellow. In a third sub-display group Pa3, when a second sub-pixel 12 to which a second pixel circuit P2 belongs and a third sub-pixel 13 to which a third pixel circuit P3 belongs emit light and perform display simultaneously, the presented emitted light is cyan. Moreover, among the light emitted from the sub-pixels in the display panel 100, when the amount of purple light is consistent the amount of yellow light and the amount of cyan light among the light emitted from the sub-pixels in the display panel 100, a display image of the display panel 100 viewed by the human eye is more inclined to cyan due to the visual sensitivity angle of the human eye to purple light. In this case, at the start moment of one frame of image, the amount of purple light with low visual sensitivity is increased, and the amount of yellow light with high visual sensitivity and the amount cyan light with high visual sensitivity are decreased. Such an arrangement can make the brightness of the purple light viewed by the human eye consistent with the brightness of the yellow light and the brightness of the cyan light. Therefore, after the purple light, the yellow light, and the cyan light are mixed in the human eye, the display image tending to be white can be viewed, thereby balancing colors of the light received by the human eye, and improving the display color cast of the display panel 100.

It may be understood that when the number of first power signal lines 31 is greater than both the number of second power signal lines 32 and the number of third power signal lines 33, the number of second power signal lines 32 may be the same as or different from the number of third power signal lines 33, which may be specifically designed according to actual needs and is not specifically limited in the embodiments of the present disclosure.

In an optional embodiment, continuing to refer to FIG. 16, among the plurality of power signal lines 3, the number of first power signal lines 31 is k1, the number of second power signal lines 32 is k2, and the number of third power signal lines 33 is k3. k1: k2: k3 =2:1:1. k1: k2: k3=2:1:1. This may be understood as that at least one first display region may exist in the display panel 100. In a first display region, a ratio of the arrangement number of first power signal lines 31, the arrangement number of second power signal lines 32, and the arrangement number of third power signal lines 33 is 2:1:1. At least one second display region may also exist in the display panel 100. In a second display region, a ratio of the arrangement number of first power signal lines 31, the arrangement number of second power signal lines 32, and the arrangement number of third power signal lines 33 may be not equal to 2:1:1. On the premise that a ratio of the entire number of first power signal lines 31, the entire number of second power signal lines 32, and the entire number of third power signal lines 33 is 2:1:1 in the display panel 100, no specific limitations are made thereto in the embodiments of the present disclosure.

In this embodiment, with the arrangement in which k1: k2: k3=2:1:1, the number of first power signal lines 31 is the sum of the number of second power signal lines 32 and the number of third power signal lines 33, and the number of second power signal lines 32 may be equal to the number of third power signal lines 33, thereby guaranteeing the overall wiring uniformity at gaps between sub-pixels of corresponding colors on the premise of improving the display color cast.

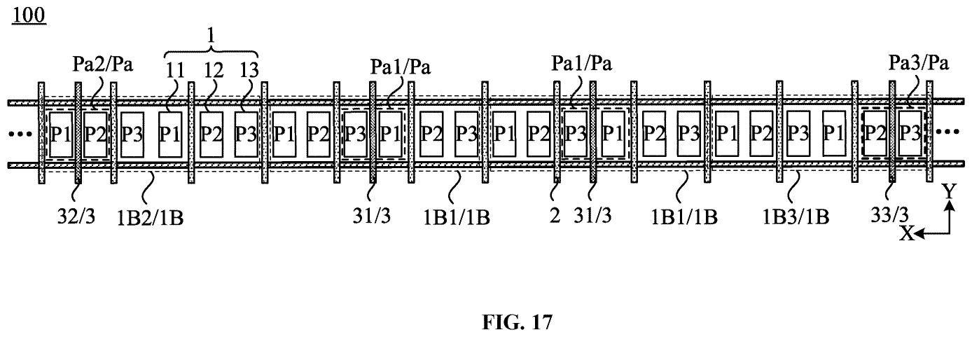

In an optional embodiment, as shown in FIG. 17, m adjacent pixel units 1 arranged in the row direction X constitute a display unit group 1B. m is a positive integer greater than or equal to 2. p adjacent display unit groups 1B include a first display unit groups 1B1, b second display unit groups 1B 2, and c third display unit groups 1B 3. p=a+b+c. Each of p, a, b, and c is a positive integer. Sub-display groups Pa of a first display unit group include a first sub-display group Pa1 provided with a first power signal line 31. Sub-display groups Pa of a second display unit group 1B2 include a second sub-display group Pa2 provided with a second power signal line 32. Sub-display groups Pa of a third display unit group 1B3 include a third sub-display group Pa3 provided with a third power signal line 33.

p=a+b+c. Each of p, a, b, and c is a positive integer so that p is a positive integer greater than or equal to 3. The specific value of p may be designed according to actual needs and is not specifically limited in the embodiments of the present disclosure. m is a positive integer greater than or equal to 2. That is, m may be equal to 2; alternatively, m may be another integer greater than 2. For ease of simplifying description and the drawings, without special limitation, an example in which m is equal to 2 is taken for exemplary description in the embodiments of the present disclosure.

Specifically, the first power signal line 31 is disposed between a first pixel circuit P1 and a third pixel circuit P3 that are in the first sub-display group Pa1. The second power signal line 32 is disposed between a first pixel circuit P1 and a second pixel circuit P2 that are in the second sub-display group Pa2. The third power signal line 33 is disposed between a second pixel circuit P2 and a third pixel circuit P3 that are in the third sub-display group Pa3. With the arrangement in which the p adjacent display unit groups 1B include the a first display unit groups 1B1, the b second display unit groups 1B2, and the c third display unit groups 1B3, the p adjacent display unit groups 1B may serve as one arrangement period of the power signal lines 3, helping with the uniform wiring of the power signal lines 3 in the display panel 100. Moreover, at the start moment of one frame of image, in sub-pixels abnormally emitting light and performing display caused by instantaneously large currents and fluctuating voltages of positive power signals PVDD, the p adjacent display unit groups 1B may include (a+b) first sub-pixels 11, (b+c) second sub-pixels 12, and (a+c) third sub-pixels 13. In this case, the first sub-pixels 11, the second sub-pixels 12, and the third sub-pixels 13 abnormally emitting light and performing display may be arranged periodically, preventing a bright display image in a certain region from being captured by the human eye due to the presence of a relatively great number of sub-pixels abnormally emitting light and performing display, thus improving the overall display uniformity of the display panel 100, making each region in the display panel 100 have relatively low display brightness at the start moment of one frame of image, alleviating the screen flicker problem, and improving the display effect of the display panel 100.

It may be understood that p power signal lines 3 may be provided in a region where the p adjacent display unit groups 1B are located. Among the p power signal lines 3, the number a of first power signal lines 31, the number b of second power signal lines 32, and the number c of third power signal lines 33 may be designed according to actual needs and are not specifically limited in the embodiments of the present disclosure.

In an optional embodiment, among the p power signal lines 3, the number a of first power signal lines 31, the number b of second power signal lines 32, and the number c of third power signal lines 33 may satisfy that a:b:c=2:1:1. With this arrangement, the number a of first power signal lines 31 is the sum of the number b of second power signal lines 32 and the number c of third power signal lines 33, thus balancing the color of a display image viewed by the human eye and thereby improving the display color cast on the premise of improving the wiring uniformity of signal lines in the display panel 100.

It needs to be noted that FIG. 17 exemplarily illustrates that among the p power signal lines 3, a first power signal line 31 is located between a second power signal line 32 and a third power signal line 33. In the embodiments of the present application, the arrangement manner of the first power signal lines 31, the second power signal lines 32, and the third power signal lines 33 may be designed according to actual needs and is not specifically limited in the embodiments of the present disclosure.

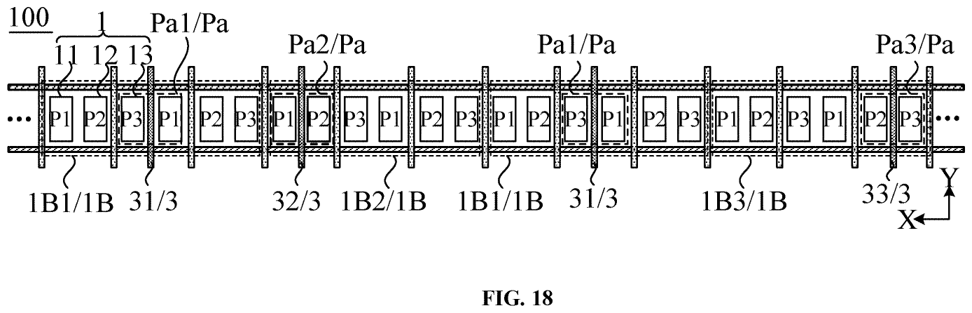

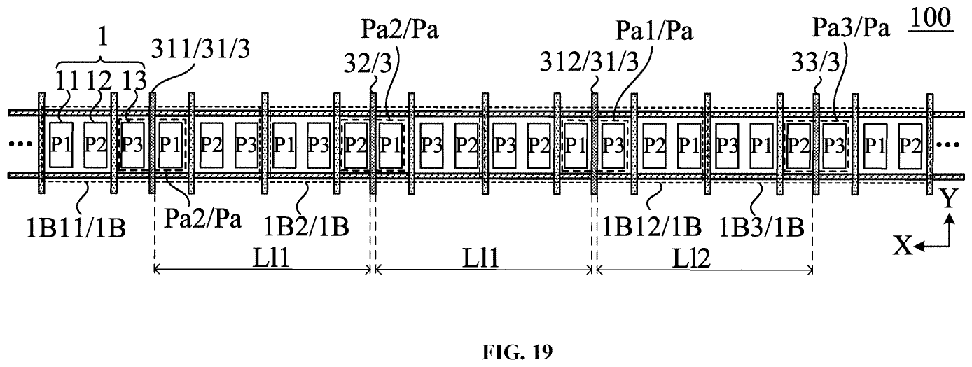

In an optional embodiment, as shown in FIG. 18, in the row direction X, four adjacent power signal lines 3 are sequentially a first power signal line 31, a second power signal line 32, a first power signal line 31, and a third power signal line 33. A second power signal line 32 and a third power signal line 33 may be spaced apart by a first power signal line 31 so that the number of first power signal lines 31 can be the sum of the number of second power signal lines 32 and the number of third power signal lines 33. In this case, the light emitted from a first sub-pixel 11 and a third sub-pixel 13 that generate abnormal display and light emission due to the coupling of a positive power signal PVDD on the first power signal line 31 can be separately combined with the light emitted from a first sub-pixel 11 and a second sub-pixel 12 that generate abnormal display and light emission due to the coupling of a positive power signal PVDD on the second power signal line 32 and the light emitted from a second sub-pixel 12 and a third sub-pixel 13 that generate abnormal display and light emission due to the coupling of a positive power signal PVDD on the third power signal line 33. Such an arrangement guarantees that the display and emission color of a display image at each position in the display panel 100 viewed by the human eye is consistent and that the display brightness at each position in the display panel 100 is relatively low.

Moreover, with the arrangement in which four adjacent power signal lines 3 are sequentially a first power signal line 31, a second power signal line 32, a first power signal line 31, and a third power signal line 33, the first power signal lines 31, the second power signal lines 32 and the third power signal lines 33 can be uniformly distributed in the display panel 100. For example, every four power signal lines 3 forms a configuration cycle of the power signal lines, preventing a relatively great number of power signal lines of a certain type in a certain region from making the region presenting abnormal display and light emission of a single color more easily captured by the human eye, thus improving the overall display uniformity of the display panel 100, and alleviating the screen flicker problem of the display panel.

It may be understood that when four adjacent power signal lines 3 are sequentially a first power signal line 31, a second power signal line 32, a first power signal line 31, and a third power signal line 33, the distance between a first power signal line 31 and a second power signal line 32 adjacent to each other may be the same as or different from the distance between a first power signal line 31 and a third power signal line 33 adjacent to each other, which may be specifically designed according to actual needs and is not specifically limited in the embodiments of the present disclosure.

In an optional embodiment, when a first sub-pixel 11, a second sub-pixel 12, and a third sub-pixel 13 in a pixel unit 1 are sequentially arranged in the row direction X, the distance between a first power signal line 31 and a second power signal line 32 adjacent to each other and the distance between a first power signal line 31 and a third power signal line 33 adjacent to each other are different distances.

In another optional embodiment, Ll1 is the distance between a first power signal line 31 and a second power signal line 32 adjacent to each other. Ll 2 is the distance between a first power signal line 31 and a third power signal line 33 adjacent to each other. Ll1 =Ll2. Such an arrangement may guarantee that the distance between two adjacent power signal lines 3 is a fixed value so that the power signal lines 3 are uniformly distributed in the display panel 100, simplifying the wiring manner of the display panel 100 and improving the display uniformity of the display panel 100.

In an optional embodiment, when four adjacent power signal lines 3 are sequentially the first first power signal line 311, a second power signal line 32, the second first power signal line 312, and a third power signal line 33, and when Ll1=Ll2, four adjacent display unit groups 1B may be the first first display unit group 1B11, a second display unit group 1B2, the second first display unit group 1B12, and a third display unit group 1B3. In the same pixel unit 1 of the first first display unit group 1B11, a first sub-pixel 11, a second sub-pixel 12, and a third sub-pixel 13 are sequentially arranged in the row direction X; in this case, the first first power signal line 311 may be located at a gap between pixel circuits of two adjacent pixel units 1 in the first first display unit group 1B11. In the same pixel unit 1 of the second display unit group 1B2, a first sub-pixel 11, a third sub-pixel 13, and a second sub-pixel 12 are sequentially arranged in the row direction X; in this case, the second power signal line 32 may be located at a gap between pixel circuits of two adjacent pixel units 1 in the second display unit group 1B2. In the same pixel unit 1 of the second first display unit group 1B12, a third sub-pixel 13, a second sub-pixel 12, and a first sub-pixel 11 are sequentially arranged in the row direction X; in this case, the second first power signal line 312 may be located at a gap between pixel circuits of two adjacent pixel units 1 in the second first display unit group 1B12. In the same pixel unit 1 of the third display unit group 1B3, a third sub-pixel 13, a first sub-pixel 11, and a second sub-pixel 12 are sequentially arranged in the row direction X; in this case, the third power signal line 33 may be located at a gap between pixel circuits of two adjacent pixel units 1 in the third display unit group 1B3. With this arrangement, a power signal line 3 may be located at a gap between pixel circuits in two adjacent pixel units 1 so that when the power signal line 3 is electrically connected to the pixel circuits in the pixel units 1 on two opposite sides of the power signal line 3, the connection consistency of the power signal line 3 to the pixel circuits in the pixel units 1 on two opposite sides of the power signal line 3 can be guaranteed, thus guaranteeing that positive power signals PVDD supplied by the power signal line 3 to the pixel circuits in the pixel units 1 at two opposite sides of the power signal line 3 are consistent, thereby improving the display uniformity of the display panel 100.

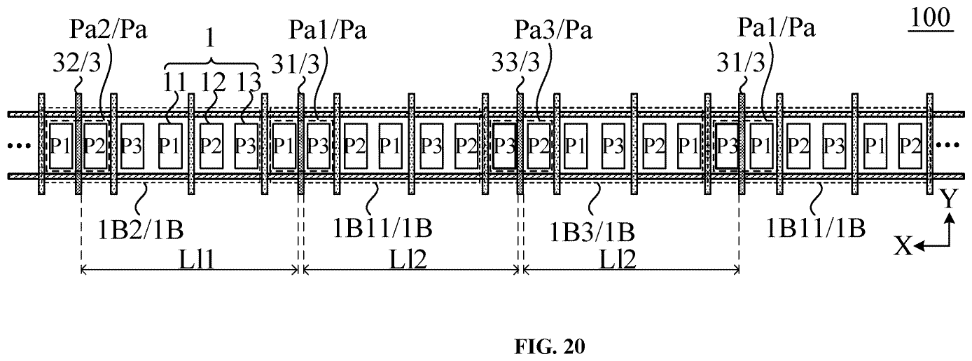

In other optional embodiments, as shown in FIG. 20, when four adjacent power signal lines 3 are sequentially a second power signal line 32, the first first power signal line 311, a third power signal line 33, and the second first power signal line 312, and when Ll1=Ll2, four adjacent display unit groups 1B may be a second display unit group 1B2, the first first display unit group 1B11, a third display unit group 1B3, and the second first display unit group 1B12. In the same pixel unit 1 of the second display unit group 1B2, a first sub-pixel 11, a second sub-pixel 12, and a third sub-pixel 13 are sequentially arranged in the row direction X; in this case, the second power signal line 32 may be located at a gap between a first pixel circuit P1 and a second pixel circuit P2 that are adjacent to each other in one of the pixel units 1 in the second display unit group 1B2. In the same pixel unit 1 of the first first display unit group 1B11, a first sub-pixel 11, a third sub-pixel 13, and a second sub-pixel 12 are sequentially arranged in the row direction X; in this case, the first first power signal line 311 may be located at a gap between a first pixel circuit P1 and a third pixel circuit P3 that are adjacent to each other in one of the pixel units 1 in the first first display unit group 1B11. In the same pixel unit 1 of the third display unit group 1B3, a third sub-pixel 13, a second sub-pixel 12, and a first sub-pixel 11 are sequentially arranged in the row direction X; in this case, the third power signal line 33 may be located at a gap between a third pixel circuit P3 and a second pixel circuit P2 that are adjacent to each other in one of the pixel units 1 in the third display unit group 1B3. In the same pixel unit 1 of the second first display unit group 1B12, a first sub-pixel 11, a third sub-pixel 13, and a second sub-pixel 12 are sequentially arranged in the row direction X; in this case, the second first power signal line 312 may be located at a gap between a third pixel circuit P3 and a first pixel circuit P1 that are adjacent to each other in one of the pixel units 1 in the second first display unit group 1B12. With this arrangement, a power signal line 3 may be located at a gap between adjacent pixel circuits in the same adjacent pixel unit 1 to guarantee the wiring uniformity of the power signal lines 3 in the display panel 100, thus improving the display uniformity of the display panel 100.

It may be understood that the specific arrangement manner of a first sub-pixel 11, a second sub-pixel 12, and a third sub-pixel 13 of the same pixel unit 1 in the display panel 100 may be designed according to actual needs and is not specifically limited in the embodiments of the present disclosure on the premise that the distance between two adjacent power signal lines 3 can be guaranteed to be a fixed value.

It needs to be noted that the distribution manner of the power signal lines is exemplarily described above merely when the pixel units 1 include the first sub-pixels 11, the second sub-pixels 12, and the third sub-pixels 13. In the embodiments of the present disclosure, the pixel units may further include other sub-pixels. When the pixel units include other sub-pixels, the distribution manner of the power signal lines needs to be adjusted according to actual needs, which may be specifically designed according to actual needs and is not specifically limited in the embodiments of the present disclosure.

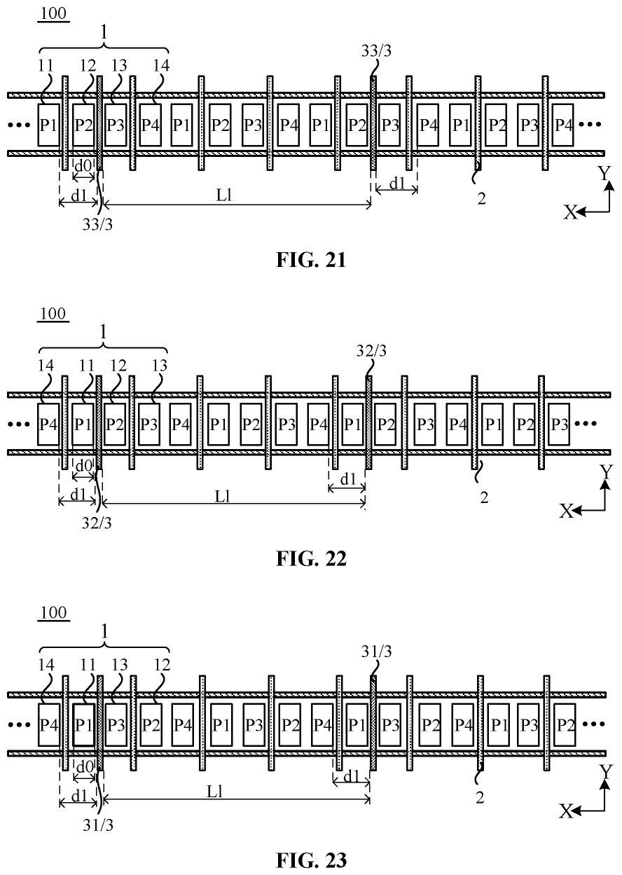

In an optional embodiment, as shown in FIGS. 21 to 23, the pixel units 1 include first sub-pixels 11, second sub-pixels 12, third sub-pixels 13, and fourth sub-pixels 14 arranged in the row direction X. A first pixel circuit P1 is a pixel circuit of a first sub-pixel 11. A second pixel circuit P2 is a pixel circuit of a second sub-pixel 12. A third pixel circuit P3 is a pixel circuit of a third sub-pixel 13. A fourth pixel circuit P4 is a pixel circuit of a fourth sub-pixel 14. The emission wavelength of the first sub-pixel 11 is greater than the emission wavelength of the second sub-pixel 12. The emission wavelength of the second sub-pixel 12 is greater than the emission wavelength of the third sub-pixel 13. The emission color of the fourth sub-pixel 14 at least includes the combined emission color of the first sub-pixel 11 and the second sub-pixel 12. In the row direction X, the distance between a power signal line 3 and the fourth pixel circuit P4 is d1. d1>d0. d0 is the dimension of a pixel circuit in the row direction X.

When the emission wavelength of the first sub-pixel 11 is greater than the emission wavelength of the second sub-pixel 12 and the emission wavelength of the second sub-pixel 12 is greater than the emission wavelength of the third sub-pixel 13, the emission color of the first sub-pixel 11 may be red, the emission color of the second sub-pixel 12 may be green, and the emission color of the third sub-pixel 13 may be blue. When the emission color of the fourth sub-pixel 14 includes the combined emission color of the first sub-pixel 11 and the second sub-pixel 12, the emission color of the fourth sub-pixel 14 may be yellow. Alternatively, the emission color of the fourth sub-pixel 14 may also include the combined emission color of the first sub-pixel 11, the second sub-pixel 12, and the third sub-pixel 13. In this case, the emission color of the fourth sub-pixel 14 may be white. The emission color of the fourth sub-pixel 14 may be designed according to actual needs and is not specifically limited in the embodiments of the present disclosure.

It may be understood that when the emission color of the fourth sub-pixel 14 is yellow, the fourth sub-pixel 14 may cooperate with the first sub-pixel 11, the second sub-pixel 12, and the third sub-pixel 13 to expand the color gamut range of the display panel 100, especially to make up for the shortcomings of the first sub-pixel 11, the second sub-pixel 12, and the third sub-pixel 13 in a yellow-green-red transition region. Moreover, an emission layer of a light-emitting element in the fourth sub-pixel 14 is made of a yellow light-emitting material. An emission layer of a light-emitting element in the first sub-pixel 11 is made of a red light-emitting material. An emission layer of a light-emitting element in the second sub-pixel 12 is made of a green light-emitting material. Generally, the conversion efficiency of the yellow light-emitting material is usually higher than the conversion efficiency of the red light-emitting material and the conversion efficiency of the green light-emitting material. Therefore, the arrangement of the fourth sub-pixel may improve the overall display brightness of the display panel to a certain extent and reduce the power consumption of the display panel.

It may also be understood that when the emission color of the fourth sub-pixel 14 is white, the fourth sub-pixel 14 can emit white light without color mixing with sub-pixels of other colors so that the fourth sub-pixel 14 has high white light emission efficiency, thus improving the display brightness of the display panel 100, improving visibility in a high-brightness environment, and reducing the power consumption of the display panel 100.

However, whether the emission color of the fourth sub-pixel 14 is yellow or white, the human eye has high visual sensitivity to the light emitted from the fourth sub-pixel 14. Therefore, when a great number of fourth sub-pixels 14 exist in the display panel 100 and abnormally perform display and emit light at the start moment of one frame of image, a display image of the display panel 100 is more easily viewed by the human eye, thus resulting in the screen flicker problem of the display panel 100.

In this embodiment, the distance between the power signal line 3 and the fourth pixel circuit P4 in the row direction X is at least d1. That is, the minimum distance between the power signal line 3 and the fourth pixel circuit P4 is d1. In other words, the distance between the power signal line 3 and the fourth pixel circuit P4 may be greater than or equal to d1. Moreover, d1 is greater than the dimension d0 of a pixel circuit in the row direction X. That is, the distance between the power signal line 3 and the fourth pixel circuit P4 in the row direction X is greater than the dimension d0 of a pixel circuit in the row direction X. In this case, the power signal line 3 and the fourth pixel circuit P4 have a relatively long distance, reducing the magnitude of a parasitic capacitance formed by the power signal line 3 and the fourth pixel circuit P4, thereby reducing the signal amount of positive power signals PVDD with instantaneously large currents and fluctuating voltages transmitted by the power signal line 3 coupled to the fourth pixel circuit P4, thus preventing the fourth pixel circuit 14 from generating bright abnormal display and light emission which would be captured by the human eye, thereby alleviating the screen flicker problem, and improving the display effect of the display panel 100.

When the distance between two adjacent pixel circuits arranged in the row direction X is less than the dimension of a pixel circuit in the row direction, with the arrangement in which the distance between the power signal line 3 and the fourth pixel circuit P4 in the row direction X is greater than the dimension d0 of a pixel circuit in the row direction X, at least one other pixel circuit is disposed between the power signal line 3 and the fourth pixel circuit P4. The at least one other pixel circuit may serve as an isolation structure between the power signal line 3 and the fourth pixel circuit P4 so that the power signal line 3 is not directly adjacent to the fourth pixel circuit P4 and no parasitic capacitance can be formed by the power signal line 3 and the fourth pixel circuit P4, thus preventing a positive power signal PVDD with an instantaneously large current and fluctuating voltage transmitted by the power signal line 3 from being coupled to the fourth pixel circuit P4 and causing a light-emitting element driven by the fourth pixel circuit P4 to present abnormal display and light emission, thereby alleviating the screen flicker problem, and improving the display effect of the display panel 100.

Additionally, when at least one other pixel circuit is disposed between the power signal line 3 and the fourth pixel circuit P4, the at least one pixel circuit isolated between the power signal line 3 and the fourth pixel circuit P4 may be at least one of a first pixel circuit P1, a second pixel circuit P2, or a third pixel circuit P3. The power signal line 3 may be disposed between a first pixel circuit P1 and a second pixel circuit P2 adjacent to each other and arranged in the row direction X. Alternatively, the power signal line 3 may be disposed between a second pixel circuit P2 and a third pixel circuit P3 adjacent to each other and arranged in the row direction X. Alternatively, the power signal line 3 may be disposed between a first pixel circuit P1 and a third pixel circuit P3 adjacent to each other and arranged in the row direction X. The corresponding relationship between the power signal line 3 and a pixel circuit may be designed according to actual needs and is not specifically limited in the embodiments of the present disclosure.

In an optional embodiment, referring to FIGS. 21, 24, and 25, in the same pixel unit 1, a first pixel circuit P1, a second pixel circuit P2, a third pixel circuit P3, and a fourth pixel circuit P4 are sequentially arranged in the row direction X. The plurality of power signal lines 3 include second power signal lines 32 and/or third power signal lines 33. A second power signal line 32 is located at a gap between the first pixel circuit P1 and the second pixel circuit P2 adjacent to each other. Moreover/alternatively, a third power signal line 33 is located at a gap between the second pixel circuit P2 and the third pixel circuit P3 adjacent to each other.

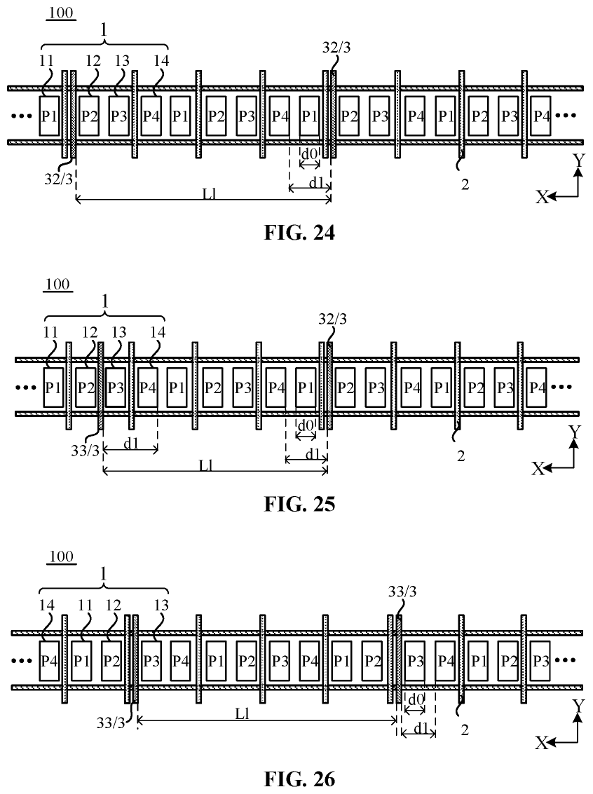

The power signal lines 3 may include the second power signal lines 32 and/or the third power signal lines 33. That is, as shown in FIG. 21, the power signal lines 3 may include only the third power signal lines 33. Alternatively, as shown in FIG. 24, the power signal lines 3 may include only the second power signal lines 32. Alternatively, as shown in FIG. 25, the power signal lines 3 may include both the second power signal lines 32 and the third power signal lines 33. This may be specifically designed according to actual needs and is not specifically limited in the embodiments of the present disclosure.

In this embodiment, the power signal lines 3 include the second power signal lines 32 and/or the third power signal lines 33. A second power signal line 32 is located at a gap between the first pixel circuit P1 and the second pixel circuit P2 adjacent to each other. A third power signal line 33 is located at a gap between the second pixel circuit P2 and the third pixel circuit P3 adjacent to each other. In this case, a third power signal line 33 is away from a fourth pixel circuit P4, preventing a positive power signal PVDD with an instantaneously large current and fluctuating voltage transmitted by the power signal line 3 from being coupled to the fourth pixel circuit P4 and causing a light-emitting element driven by the fourth pixel circuit P4 to present abnormal display and light emission, thereby alleviating the screen flicker problem, and improving the display effect of the display panel 100.

It needs to be noted that the arrangement manner of pixel circuits in the same pixel unit is merely exemplarily described above. In the embodiments of the present disclosure, the arrangement manner of pixel circuits in the same pixel unit is not limited thereto, which may be specifically designed according to actual needs and is not specifically limited in the embodiments of the present disclosure.

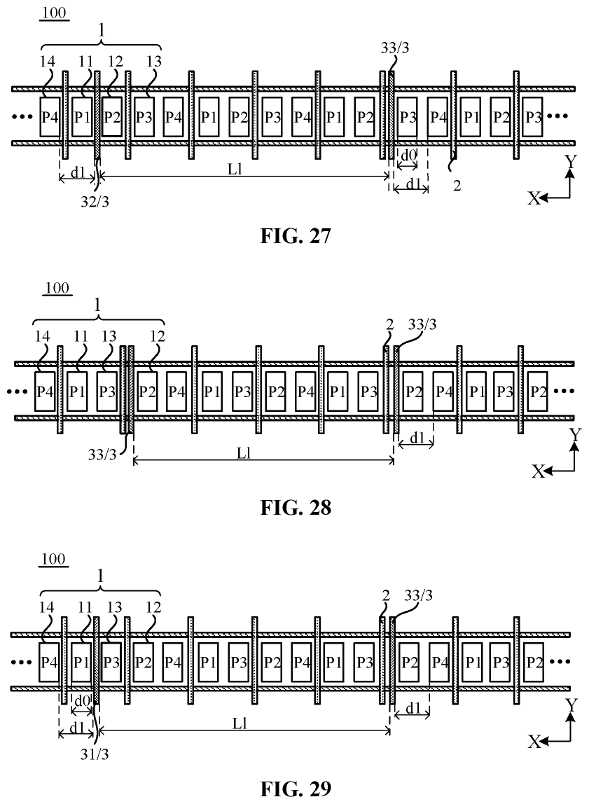

In an optional embodiment, referring to FIGS. 22, 26, and 27, in the same pixel unit 1, a fourth pixel circuit P4, a first pixel circuit P1, a second pixel circuit P2, and a third pixel circuit P3 are sequentially arranged in the row direction X. In this case, the power signal lines 3 may include second power signal lines 32 and/or third power signal lines 33. A second power signal line 32 is located at a gap between the first pixel circuit P1 and the second pixel circuit P2 adjacent to each other. A third power signal line 33 is located at a gap between the second pixel circuit P2 and the third pixel circuit P3 adjacent to each other.

In another optional embodiment, referring to FIGS. 23, 28, and 29, in the same pixel unit 1, a fourth pixel circuit P4, a first pixel circuit P1, a third pixel circuit P3, and a second pixel circuit P2 are sequentially arranged in the row direction X. In this case, the power signal lines 3 may include first power signal lines 31 and/or third power signal lines 33. A first power signal line 31 is located at a gap between the first pixel circuit P1 and the third pixel circuit P3 adjacent to each other. A third power signal line 33 is located at a gap between the third pixel circuit P3 and the second pixel circuit P2 adjacent to each other.

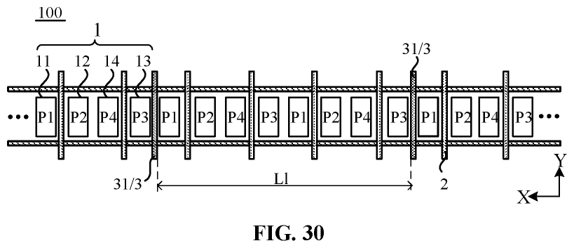

In another optional embodiment, referring to FIGS. 23 and 30, in the same pixel unit 1, a first pixel circuit P1 is adjacent to a third pixel circuit P3. Alternatively, in two adjacent pixel units 1, a first pixel circuit P1 is adjacent to a third pixel circuit P3. The plurality of power signal lines 3 include first power signal lines 31. A first power signal line 31 is located at a gap between a first pixel circuit P1 and a third pixel circuit P3 adjacent to each other.

When a first pixel circuit P1 and a third pixel circuit P3 adjacent to each other exist among pixel circuits arranged in the row direction, the power signal lines 3 may include a first power signal line 31 located between the first pixel circuit P1 and the third pixel circuit P3 adjacent to each other and arranged in the row direction. In this case, only the first power signal lines 31 may be disposed in the display panel 100 so that at the start moment of one frame of image, positive power signals PVDD with instantaneously large currents and fluctuating voltages are coupled to only part of the first pixel circuits P1 and the third pixel circuits P3 and are coupled to no second pixel circuit P2 or fourth pixel circuit P4. In this case, the display and light emission caused by the coupling action of the positive power signals PVDD with the instantaneously large currents and fluctuating voltages may tend to be purple. That is, the color of a display image presented by the display panel 100 tends to be less sensitive to the human eye, thus alleviating the screen flicker problem of the display panel 100 and improving the display effect of the display panel 100.

It needs to be noted that the case where pixel circuits in various pixel units are arranged in the same manner is merely exemplified above. In the embodiments of the present disclosure, pixel circuits in various pixel units may also be arranged in different manners. The specific arrangement manner of pixel circuits in various pixel units and the specific arrangement manner of the power signal lines are not limited in the embodiments of the present disclosure on the premise that the distance between a power signal line and a fourth pixel circuit in the row direction is greater than the dimension of one pixel circuit in the row direction.

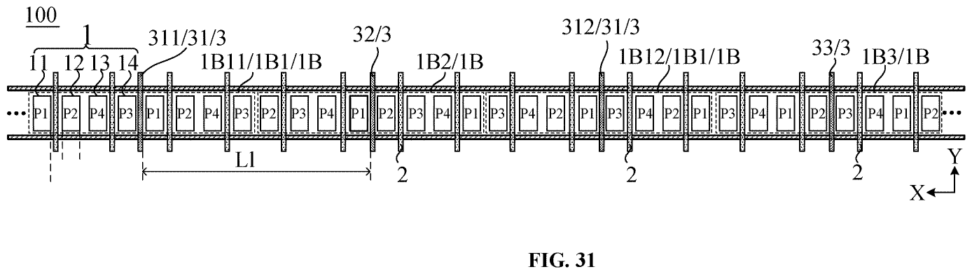

Optionally, as shown FIG. 31, m adjacent pixel units 1 constitute a display unit group 1B. A power signal line is electrically connected to pixel circuits in the same display unit group. m is a positive integer. p adjacent display unit groups 1B include a first display unit groups 1B1, b second display unit groups 1B2, and c third display unit groups 1B 3. p=a+b+c. Each of p, a, b, and c is a positive integer. A first display unit group 1 B1 includes a first pixel circuit P1 and a third pixel circuit P3 adjacent to each other, and a power signal line electrically connected to pixel circuits in the first display unit group 1 B1 is located at a gap between the first pixel circuit P1 and the third pixel circuit P3 adjacent to each other. A second display unit group 1B2 includes a first pixel circuit P1 and a second pixel circuit P2 adjacent to each other, and a power signal line electrically connected to pixel circuits in the second display unit group 1B2 is located at a gap between the first pixel circuit P1 and the second pixel circuit P2 adjacent to each other. A third display unit group 1B3 includes a second pixel circuit P2 and a third pixel circuit P3 adjacent to each other, and a power signal line electrically connected to pixel circuits in the third display unit group 1B3 is located at a gap between the second pixel circuit P2 and the third pixel circuit P3 adjacent to each other.

p=a+b+c. Each of p, a, b, and c is a positive integer so that p is a positive integer greater than or equal to 3. The specific value of p may be specifically designed according to actual needs and is not specifically limited in the embodiments of the present disclosure. m is a positive integer greater than or equal to 2. That is, m may be equal to 2; alternatively, m may be another integer greater than 2. For ease of simplifying description and the drawings, without special limitation, an example in which m is equal to 2 is taken for exemplary description in the embodiments of the present disclosure.

Specifically, with the arrangement in which the p adjacent display unit groups 1B include the first display unit groups 1B1, the b second display unit groups 1B2, and the c third display unit groups 1B3, the p adjacent display unit groups 1B may form the configuration cycle of the power signal lines 3, helping with the uniform wiring of the power signal lines 3 in the display panel 100. Moreover, the power signal line 3 electrically connected to the pixel circuits in the first display unit group 1B1 is located between the first pixel circuit P1 and the third pixel circuit P3 adjacent to each other. The power signal line 3 electrically connected to the pixel circuits in the second display unit group 1B2 is located between the first pixel circuit P1 and the second pixel circuit P2 adjacent to each other. The power signal line 3 electrically connected to the pixel circuits in the third display unit group 1B3 is located between the second pixel circuit P2 and the pixel circuit P3 adjacent to each other. In this case, at the start moment of one frame of image, in sub-pixels abnormally emitting light and performing display caused by instantaneously large currents and fluctuating voltages of positive power signals PVDD, the p adjacent display unit groups 1B may include (a+b) first sub-pixels 11, (b+c) second sub-pixels 12, and (a+c) third sub-pixels 13. In this case, the first sub-pixels 11, the second sub-pixels 12, and the third sub-pixels 13 abnormally emitting light and performing display may be arranged periodically, preventing a bright display image in a certain region from being captured by the human eye due to the presence of a relatively great number of sub-pixels abnormally emitting light and performing display, thus improving the overall display uniformity of the display panel 100, making each region in the display panel 100 have relatively low display brightness at the start moment of one frame of image, alleviating the screen flicker problem, and improving the display effect of the display panel 100.

It may be understood that when the power signal line 3 located between the first pixel circuit P1 and the third pixel circuit P3 adjacent to each other is a first power signal line 31, when the power signal line 3 located between the first pixel circuit P1 and the second pixel circuit P2 adjacent to each other is a second power signal line 32, and when the power signal line 3 located between the second pixel circuit P2 and the pixel circuit P3 adjacent to each other is a third power signal line 33, p power signal lines 3 may be disposed in a region where the p adjacent display unit groups 1B are located. Among the p power signal lines 3, the number a of first power signal lines 31, the number b of second power supply signal lines 32, and the number c of third power signal lines 33 may be designed according to actual needs and are not specifically limited in the embodiments of the present disclosure.

In an optional embodiment, continuing to refer to FIG. 31, among the p power signal lines 3, the number a of first power signal lines 31, the number b of second power signal lines 32, and the number c of third power signal lines 33 may satisfy that a:b:c=2:1:1. With this arrangement, the number a of first power signal lines 31 is the sum of the number b of second power signal lines 32 and the number c of third power signal lines 33, thus balancing the color of a display image viewed by the human eye and thereby improving the display color cast on the premise of improving the wiring uniformity of signal lines in the display panel 100.

It may be understood that when four adjacent power signal lines 3 are sequentially a first power signal line 31, a second power signal line 32, a first power signal line 31, and a third power signal line 33, the distance Ll1 between a first power signal line 31 and a second power signal line 32 adjacent to each other may be the same as or different from the distance Ll2 between a first power signal line 31 and a third power signal line 33 adjacent to each other, which may be specifically designed according to actual needs and is not specifically limited in the embodiments of the present disclosure.

In an optional embodiment, continuing to refer to FIG. 31, when four adjacent power signal lines 3 are sequentially the first first power signal line 311, a second power signal line 32, the second first power signal line 312, and a third power signal line 33, and when Ll1=Ll2, four adjacent display unit groups 1B may be the first first display unit group 1B11, a second display unit group 1B2, the second first display unit group 1B12, and a third display unit group 1B3. In the same pixel unit 1 of the first first display unit group 1B11, a first pixel unit P1, a second pixel unit P2, a fourth pixel unit P4, and a third pixel unit P3 are sequentially arranged in the row direction X; in this case, the first first power signal line 311 may be located at a gap between pixel circuits of two adjacent pixel units 1 in the first first display unit group 1B11. In the same pixel unit 1 of the second display unit group 1B2, a second pixel unit P2, a third pixel unit P3, a fourth pixel unit P4, and a first sub-pixel P1 are sequentially arranged in the row direction X; in this case, the second power signal line 32 may be located at a gap between pixel circuits of two adjacent pixel units 1 in the second display unit group 1B2. In the same pixel unit 1 of the second first display unit group 1B12, a third pixel unit P3, a fourth pixel unit P4, a second pixel unit P2, and a first pixel unit P1 are sequentially arranged in the row direction X; in this case, the second first power signal line 312 may be located at a gap between pixel circuits of two adjacent pixel units 1 in the second first display unit group 1B12. In the same pixel unit 1 of the third display unit group 1B3, a third pixel unit P3, a fourth pixel unit P4, a first sub-pixel P1, and a second pixel unit P2 are sequentially arranged in the row direction X; in this case, the third power signal line 33 may be located at a gap between pixel circuits of two adjacent pixel units 1 in the third display unit group 1B3. With this arrangement, a power signal line 3 may be located at a gap between pixel circuits in two adjacent pixel units 1 so that when the power signal line 3 is electrically connected to the pixel circuits in the pixel units 1 on two opposite sides of the power signal line 3, the connection consistency of the power signal line 3 to the pixel circuits in the pixel units 1 on two opposite sides of the power signal line 3 can be guaranteed, thus guaranteeing that positive power signals PVDD supplied by the power signal line 3 to the pixel circuits in the pixel units 1 on two opposite sides of the power signal line 3 are consistent, thereby improving the display uniformity of the display panel 100.

It needs to be noted that the arrangement manner of the power signal lines in different pixel arrangement manners is merely exemplified above. The arrangement manner of the power signal lines is not limited thereto on the premise that the core inventive point of the embodiments of the present disclosure can be implemented. Accordingly, when the display panel includes both the power signal lines and the data signal lines, the arrangement positions of the data signal lines may be adjusted according to the arrangement positions of the power signal lines, or the arrangement positions of the power signal lines may also be adjusted according to the arrangement manner of the data signal lines, which may be specifically designed according to actual needs and is not specifically limited in the embodiments of the present disclosure.

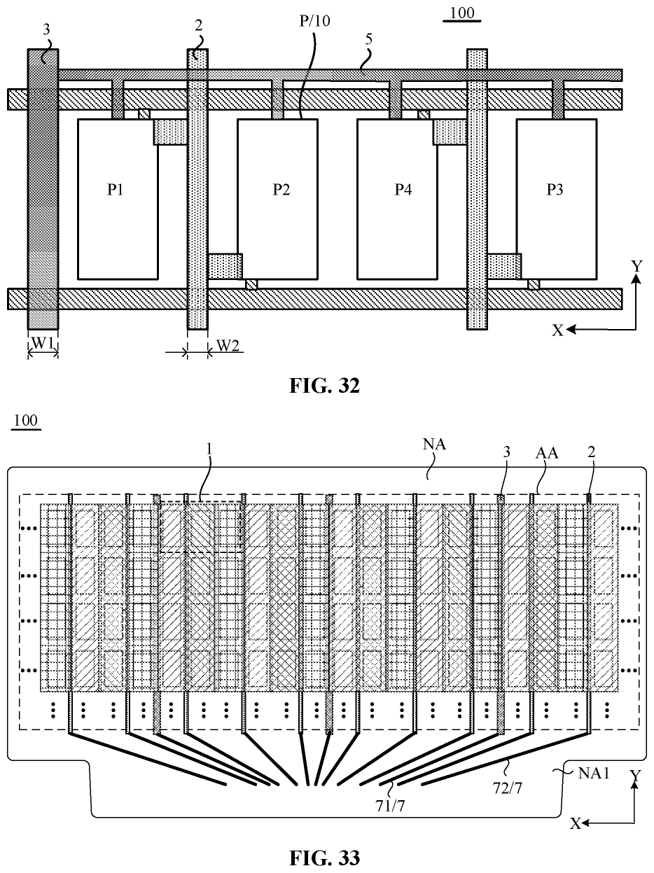

In an optional embodiment, referring to FIGS. 11 and 32, a data signal line 2 is located at a gap between two adjacent pixel circuits P electrically connected to the data signal line 2 and arranged in the row direction X.

The gap between the data signal line 2 and each of the pixel circuits P located at two opposite sides of the data signal line 2 may be consistent. In this case, when the data signal line 2 is electrically connected to the pixel circuits P at two opposite sides of the data signal line 2, the connection path between the data signal line 2 and each pixel circuit P may be consistent so that the transmission impedance of a data signal supplied to each pixel circuit P may be consistent. Therefore, a data signal received by each pixel circuit P can be consistent, thereby improving the display uniformity of the display panel 100.

On the basis of the preceding embodiments, optionally, pixel circuits P of two adjacent sub-pixels 10 electrically connected to the same data signal line 2 are centrally symmetrical about the data signal line 2. In this case, with the data signal line 2 as a symmetry axis, pixel circuits P on two sides can have a consistent signal transmission path length, consistent parasitic capacitance distribution, and consistent pixel circuit layout, simplifying the design of the pixel circuits and improving the display uniformity of the display panel 100.

On the basis of the preceding embodiments, optionally, continuing to refer to FIGS. 11 and 32, a pixel gap is a gap between two adjacent pixel circuits P arranged in the row direction X. A power signal line 3 and a data signal line 2 are disposed in different pixel gaps, respectively. In this case, only one of a power signal line 3 or a data signal line 2 may be disposed at a gap between two adjacent pixel circuits P, thereby preventing the power supply signal line 3 and the data signal line 2 from being accumulated in the same pixel gap, helping with the wiring uniformity of signal lines in the display panel 100, simplifying the design of the display panel 100, and guaranteeing a consistent parasitic capacitance between various pixel circuits P and various signal lines, thus improving the display uniformity of the display panel 100.

On the basis of the preceding embodiments, optionally, continuing to refer to FIGS. 11 and 32, W1 is the line width of a power signal line 3. W2 is the line width of a data signal line 2. 2×W2≤W1≤6×W2.

The data signal line 2 is electrically connected to pixel circuits P in two adjacent columns. The power signal line 3 is electrically connected to pixel circuits P in multiple columns. Moreover, a positive power signal transmitted by the power signal line 3 is usually a fixed-voltage signal so that the voltage drop of the positive power signal caused by the transmission path cannot be compensated for. The arrangement in which the line width W1 of the power signal line 3 is greater than the line width W2 of the data signal line 2 can guarantee a relatively great width of the power signal line 3 so that the power signal line 3 per unit length has low impedance, thus reducing the impedance of the positive power signal PVDD transmitted by the power signal line 3, improving the accuracy of the positive power signal PVDD received by a pixel circuit P, enabling the pixel circuit P to accurately drive a light-emitting element electrically connected to the pixel circuit P to emit light and perform display, and thus improving the display quality of the display panel 100.

It may be understood that the greater the line width of the power signal line 3, the larger the cross-sectional area of the power signal line 3, and the smaller the impedance of the power signal line 3 per unit length. However, when the power signal line 3 has a relatively great line width, the power signal line 3 occupies a relatively large space, not helping with the high resolution of the display panel 100. Therefore, the line width W1 of the power signal line 3 and the line width W2 of the data signal line 2 satisfy that 2×W2≤W1≤6×W2, guaranteeing the resolution of the display panel 100 and thus improving the display effect of the display panel 100 on the premise of guaranteeing a relatively small impedance of the power signal line 3.

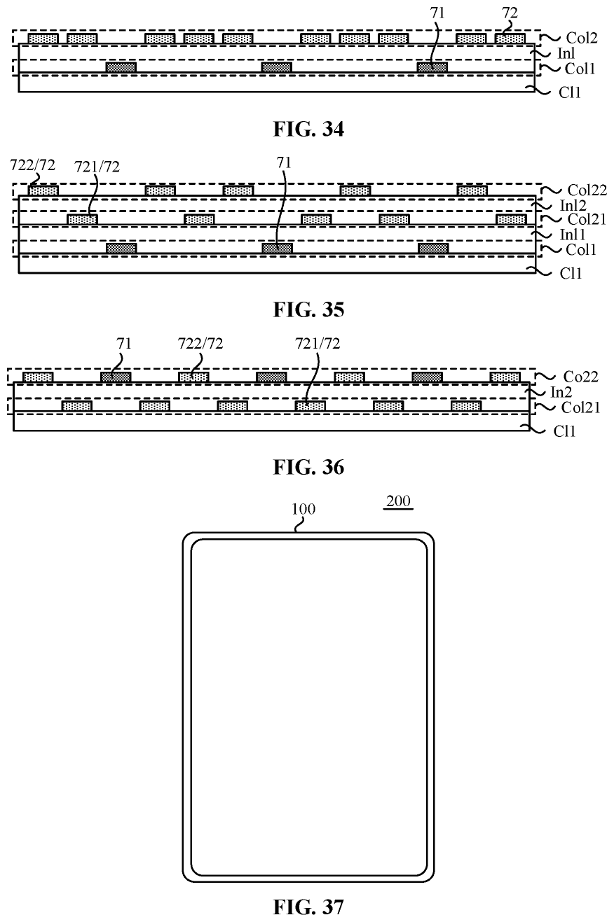

On the basis of the preceding embodiments, optionally, as shown in FIGS. 33 and 34, the display panel 100 may include a display region AA and a non-display region NA surrounding the display region AA. The pixel units 1, the power signal lines 3, and the data signal lines 2 are located in the display region AA. The non-display region NA includes a fan-out region NA1 located on one side of the display region AA. The fan-out region NA1 is provided with a plurality of fan-out wires 7. The plurality of fan-out wires 7 include a plurality of first fan-out wires 71 and a plurality of second fan-out wires 72, where the first fan-out wires 71 correspond to the plurality of power signal lines 3, and the second fan-out wires 72 correspond to the plurality of data signal lines 2. The first fan-out wires 71 are electrically connected to the power signal lines 3, respectively. The second fan-out wires 72 are electrically connected to the data signal lines 2, respectively. The display panel 100 further includes at least one conductive layer (Col1 and Col2). The fan-out wires 7 are located in the same conductive layer Col1.

It may be understood that the display panel 100 may include at least one conductive layer. That is, the display panel 100 may include one or more conductive layers. When the display panel 100 includes multiple conductive layers, an insulating layer is disposed between two adjacent conductive layers. For example, when the display panel 100 includes a conductive layer Col1 and a conductive layer Col2, both the conductive layer Col1 and the conductive layer Col2 may be insulated from each other and spaced apart on one side of the base substrate C11. In this case, an insulating layer In1 may be disposed between the conductive layer Col1 and the conductive layer Col2 so that the conductive layer Col1 and the conductive layer Col2 are insulated from each other. Moreover, when the display panel 100 includes multiple conductive layers, the multiple conductive layers may be prepared using the same or different conductive materials so that the conductivity of the multiple conductive layers may be the same or different, which may be specifically designed according to actual needs and is not specifically limited in the embodiments of the present disclosure.

The first fan-out wires 71 are electrically connected to the power signal lines 3, respectively so that the power signal lines 3 receive positive power signals supplied by a power management chip or a flexible circuit board through the first fan-out wires 71. The arrangement in which the first fan-out wires 71 are located in the same conductive layer Col1 enables the fan-out wires 7 to have the same conductivity, thus guaranteeing the consistent signal transmission impedance of the first fan-out wires 71, making positive power signals received by the power signal lines 3 keep consistent, and thereby improving the display uniformity of the display panel 100.

Additionally, when the first fan-out wires 71 are located in the same conductive layer Col1, the second fan-out wires 72 electrically connected to the data signal lines 2 respectively may also located in the same conductive layer Col2 to guarantee the consistent signal transmission impedance of the second fan-out wires 72, making positive power signals received by the data signal lines 2 keep consistent, and thereby improving the display uniformity of the display panel 100.

In other optional embodiments, as shown in FIGS. 33 and 35, the at least one conductive layer includes a first conductive layer Col21 and a second conductive layer Col22. The first conductive layer Col21 and the second conductive layer Col22 are insulated from each other and spaced apart. Two adjacent second fan-out wires 72 are located on the first conductive layer Col21 and the second conductive layer Col22, respectively.

When the at least one conductive layer includes the first conductive layer Col21 and the second conductive layer Col22 that are insulated from each other and spaced apart, an insulating layer In1 may be disposed between the first conductive layer Col21 and the second conductive layer Col22 so that a structure in the first conductive layer Col21 and a structure in the second conductive layer Col22 are insulated from each other.

The second fan-out wires 72 are electrically connected to the data signal lines 2, respectively. In this case, the number of second fan-out wires 72 is consistent with the number of data signal lines 2. When the number of second fan-out wires 72 is relatively greater, the wiring density of the second fan-out wires 72 in the fan-out region NA1 is relatively greater so that the distance between two adjacent second fan-out wires 72 is relatively short, easily causing signal crosstalk. Accordingly, two adjacent second fan-out wires 72 are located on the first conductive layer Col21 and the second conductive layer Col22, respectively. For example, two adjacent second fan-out wires 72 are the first second fan-out wire 721 and the second second fan-out wire 722. The first second fan-out wire 721 may be located in the first conductive layer Col21. The second second fan-out wire 722 may be located in the second conductive layer Col22. In this case, two adjacent second fan-out wires 72 are located in the first conductive layer Col21 and the second conductive layer Col22 alternately, reducing the wiring density of second fan-out wires 72 in one conductive layer, increasing the distance between second fan-out wires 72 in the same conductive layer, and alleviating the signal crosstalk problem. Moreover, two adjacent second fan-out wires 72 are located in the first conductive layer Col21 and the second conductive layer Col22 alternately so that a relatively great angle exists between a second fan-out wire 72 and the column direction Y, thus reducing the occupied space of the second fan-out wire 72 in the column direction Y and helping with the narrow bezel of the display panel 100.

It may be understood that the first fan-out wires 71 and the second fan-out wire 72 may be located in different conductive layers, respectively. In this case, an insulating layer Inl1 may be disposed between the conductive layer Col1 for arranging the first fan-out wires 71 and a conductive layer (Col21) for arranging the second fan-out wires 72 so that the first fan-out wires 71 and the second fan-out wire 72 are insulated from each other. Positive power signals transmitted by the first fan-out wires 71 and positive power signals transmitted by the second fan-out wires 72 do not interfere with each other.

It needs to be noted that the case where the first fan-out wires and the second fan-out wires are located in different conductive layers, respectively is merely exemplified above. In the embodiments of the present disclosure, part of the first fan-out wires and part of the second fan-out wires may be located in the same conductive layer in the display panel, which may be specifically designed according to actual needs and is not specifically limited in the embodiments of the present disclosure.

In an optional embodiment, referring to FIGS. 33 and 36, the display panel 100 includes a display region AA and a non-display region NA surrounding the display region AA. The pixel units 1, the power signal lines 3, and the data signal lines 2 are located in the display region AA. The non-display region NA includes a fan-out region NA1 located on one side of the display region AA. The fan-out region NA1 is provided with a plurality of fan-out wires 7. The plurality of fan-out wires 7 include a plurality of first fan-out wires 71 and a plurality of second fan-out wires 72, where the first fan-out wires 71 correspond to the plurality of power signal lines 3, and the second fan-out wires 72 correspond to the plurality of data signal lines 2. The first fan-out wires 71 are electrically connected to the power signal lines 3, respectively. The second fan-out wires 72 are electrically connected to the data signal lines 2, respectively. The display panel includes a first conductive layer Col21 and a second conductive layer Col22. The first conductive layer Col21 and the second conductive layer Col22 are insulated from each other and spaced apart. Two adjacent fan-out wires 7 are located on the first conductive layer Col21 and the second conductive layer Col22, respectively.

Two adjacent fan-out wires 7 arranged in the row direction of the pixel circuits 1 may be a first fan-out wire 71 and a second fan-out wire 72 and may also be two second fan-out wires 72. The arrangement in which two adjacent fan-out wires 7 are located in the first conductive layer Col21 and the second conductive layer Col22, respectively can reduce the density of fan-out wires 7 disposed in the same conductive layer, reduce the signal crosstalk between the fan-out wires 7, relatively reduce the space occupied by the fan-out wires 7 in the column direction Y, and help with the narrow bezel of the display panel 100. Moreover, two adjacent fan-out wires 7 may be a first fan-out wire 71 and a second fan-out wire 72 and may also be two second fan-out wires 72. In this case, part of the second fan-out wires 72 may be located in the same conductive layer as the first fan-out wires 71 so that no additional layer needs to be provided for the first fan-out wires 71 or the second fan-out wires 72, simplifying the layer structure of the display panel 100 and helping with the lightweight design of the display panel 100.

It may be understood that when two adjacent fan-out wires 7 are located in the first conductive layer Col21 and the second conductive layer Col22, respectively, the plurality of fan-out wires 7 may be located in the same conductive layer or may be distributed in the first conductive layer Col21 and the second conductive layer Col22, which may be specifically designed according to actual needs and is not specifically limited in the embodiments of the present disclosure.

Based on the same inventive concept, the embodiments of the present disclosure further provide a display device. The display device includes the display panel described in any embodiment of the present disclosure. Therefore, the display device has the technical features of the display panel provided in the embodiments of the present disclosure and can achieve the beneficial effects of the display panel provided in the embodiments of the present disclosure. Similarities may be referred to the preceding description of the display panel provided in the embodiments of the present disclosure and are not repeated herein.

Exemplarily, FIG. 37 is a structural diagram of a display device according to an embodiment of the present disclosure. As shown in FIG. 37, the display device includes the display panel 100 provided in the embodiments of the present disclosure. The display device 200 provided in the embodiments of the present disclosure may be any electronic product with display function, including but not limited to the following categories: phone, television, laptop, desktop display, tablet computer, digital camera, smart bracelet, smart glasses, vehicle-mounted display, medical equipment, industrial control equipment, touch interactive terminal, etc., and no special limitations are made thereto in the embodiments of the present disclosure.

It is to be noted that the preceding are preferred embodiments of the present disclosure and technical principles used therein. It is to be understood by those skilled in the art that the present disclosure is not limited to the embodiments described herein. For those skilled in the art, various apparent modifications, adaptations, combinations, and substitutions can be made without departing from the scope of the present disclosure. Therefore, while the present disclosure is described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising a plurality of pixel units arranged in an array, a plurality of power signal lines, and a plurality of data signal lines; wherein
a pixel unit among the plurality of pixel units comprises a plurality of sub-pixels of different emission colors, and a sub-pixel among the plurality of sub-pixels comprises a pixel circuit and a light-emitting element electrically connected to each other;
pixel circuits in two adjacent columns are electrically connected to a same data signal line; and
the plurality of power signal lines are arranged in a row direction of the plurality of pixel units and extend in a column direction of the plurality of pixel units, and a distance between two adjacent power signal lines is Ll, Ll≥Lp, and Lp is a dimension of one of the plurality of pixel units in the row direction.

2. The display panel of claim 1, wherein the distance between the two adjacent power signal lines is 2n×Lp, 1≤n≤5, and n is a positive integer.

3. The display panel of claim 1, wherein a power signal line among the plurality of power signal lines is electrically connected to pixel circuits in 2n pixel units arranged in the row direction among the plurality of pixel units, and n is a positive integer.

4. The display panel of claim 3, wherein n adjacent pixel units arranged in the row direction among the plurality of pixel units constitute a pixel unit group; and
the power signal line is electrically connected to pixel circuits in two pixel unit groups at two opposite sides of the power signal line separately.

5. The display panel of claim 4, wherein the power signal line is located at a gap between two adjacent pixel unit groups arranged in the row direction.

6. The display panel of claim 1, wherein the plurality of pixel units comprise a first sub-pixel, a second sub-pixel, and a third sub-pixel arranged in the row direction;
a first pixel circuit is a pixel circuit of the first sub-pixel, a second pixel circuit is a pixel circuit of the second sub-pixel, and a third pixel circuit is a pixel circuit of the third sub-pixel;
an emission wavelength of the first sub-pixel is greater than an emission wavelength of the second sub-pixel, and an emission wavelength of the second sub-pixel is greater than an emission wavelength of the third sub-pixel;
two adjacent pixel circuits arranged in the row direction constitute a sub-display group, sub-display groups comprise a first sub-display group, and two pixel circuits in the first sub-display group are a first pixel circuit and a third pixel circuit; and
the plurality of power signal lines comprise a first power signal line located at a gap between the two adjacent pixel circuits in the first sub-display group.

7. The display panel of claim 6, wherein the sub-display groups further comprise a second sub-display group and a third sub-display group;
two pixel circuits in the second sub-display group are a first pixel circuit and a second pixel circuit, and two pixel circuits in the third sub-display group are a second pixel circuit and a third pixel circuit; and
the plurality of power signal lines comprise a second power signal line and a third power signal line, wherein the second power signal line is located at a gap between the two adjacent pixel circuits in the second sub-display group, and the third power signal line is located at a gap between the two adjacent pixel circuits in the third sub-display group.

8. The display panel of claim 7, wherein among the plurality of power signal lines, the number of first power signal lines is greater than the number of second power signal lines, and the number of first power signal lines is greater than the number of third power signal lines.

9. The display panel of claim 8, wherein among the plurality of power signal lines, the number of first power signal lines is k1, the number of second power signal lines is k2, and the number of third power signal lines is k3;
wherein k1: k2: k3=2:1:1.

10. The display panel of claim 9, wherein in the row direction, four adjacent power signal lines among the plurality of power signal lines are sequentially a first power signal line, a second power signal line, a first power signal line, and a third power signal line.

11. The display panel of claim 10, wherein Ll1 is a distance between the first power signal line and the second power signal line closest to the first power signal line, and Ll3 is a distance between the first power signal line and the third power signal line closest to the first power signal line, wherein Ll1=Ll3.

12. The display panel of claim 7, wherein m adjacent pixel units arranged in the row direction among the plurality of pixel units constitute a display unit group, and m is a positive integer greater than or equal to 2;
p adjacent display unit groups comprise a first display unit groups, b second display unit groups, and c third display unit groups; wherein p=a+b+c; and each of p, a, b, and c is a positive integer; and
a sub-display group of a first display unit group comprises a first sub-display group provided with a first power signal line, a sub-display group of a second display unit group comprises a second sub-display group provided with a second power signal line, and a sub-display group of a third display unit group comprises a third sub-display group provided with a third power signal line.

13. The display panel of claim 1, wherein the plurality of pixel units comprise a first sub-pixel, a second sub-pixel, a third sub-pixel, and a fourth sub-pixel arranged in the row direction;
a first pixel circuit is a pixel circuit of the first sub-pixel; a second pixel circuit is a pixel circuit of the second sub-pixel; a third pixel circuit is a pixel circuit of the third sub-pixel;
and a fourth pixel circuit is a pixel circuit of the fourth sub-pixel;
an emission wavelength of the first sub-pixel is greater than an emission wavelength of the second sub-pixel, an emission wavelength of the second sub-pixel is greater than an emission wavelength of the third sub-pixel, and an emission color of the fourth sub-pixel at least comprises a combined emission color of the first sub-pixel and the second sub-pixel; and
in the row direction, a distance between a power signal line among the plurality of power signal lines and the fourth pixel circuit is at least d1, wherein d1>d0, and d0 is a dimension of a pixel circuit in the row direction.

14. The display panel of claim 13, wherein in a same pixel unit among the plurality of pixel units, a first pixel circuit, a second pixel circuit, a third pixel circuit, and a fourth pixel circuit are sequentially arranged in the row direction; and
the plurality of power signal lines comprise a second power signal line located at a gap between the first pixel circuit and the second pixel circuit closest to the first pixel circuit, and/or the plurality of power signal lines comprise a third power signal line located at a gap between the second pixel circuit and the third pixel circuit closest to the second pixel circuit.

15. The display panel of claim 13, wherein in a same pixel unit among the plurality of pixel units, a first pixel circuit is disposed closest to a third pixel circuit; or in two adjacent pixel units among the plurality of pixel units, a first pixel circuit is disposed closest to a third pixel circuit; and the plurality of power signal lines comprise a first power signal line located at a gap between a first pixel circuit and a third pixel circuit closest to the first pixel circuit.

16. The display panel of claim 13, wherein m adjacent pixel units among the plurality of pixel units constitute a display unit group, and the power signal line is electrically connected to pixel circuits in a same display unit group, and m is a positive integer;
p adjacent display unit groups comprise a first display unit groups, b second display unit groups, and c third display unit groups; wherein p=a+b+c; and each of p, a, b, and c is a positive integer;
a first display unit group among the a first display unit groups comprises a first pixel circuit and a third pixel circuit closest to the first pixel circuit, and a power signal line electrically connected to pixel circuits in the first display unit group is located at a gap between the first pixel circuit and the third pixel circuit closest to the first pixel circuit;
a second display unit group among the b second display unit groups comprises a first pixel circuit and a second pixel circuit closest to the first pixel circuit, and a power signal line electrically connected to pixel circuits in the second display unit group is located at a gap between the first pixel circuit and the second pixel circuit closest to the first pixel circuit; and
a third display unit group among the c third display unit groups comprises a second pixel circuit and a third pixel circuit adjacent to each other, and a power signal line electrically connected to pixel circuits in the third display unit group is located at a gap between the second pixel circuit and the third pixel circuit closest to the second pixel circuit.

17. The display panel of claim 1, further comprising a plurality of power connection lines extending in the row direction;
wherein a power signal line among the plurality of power signal lines is connected to the pixel circuit through a power connection line among the plurality of power connection lines.

18. The display panel of claim 17, wherein a line width of the power connection line in the column direction is W3, a line width of the power signal line in the row direction is W1, and W1>W3; or
wherein in the power signal line and the power connection line connected to each other, a distance between the power signal line and a pixel circuit closest to the power signal line in the row direction is a1, and a distance between the power connection line and a pixel circuit closest to the power connection line in the row direction is a2, wherein a2>a1.

19. The display panel of claim 17, further comprising a plurality of first signal lines extending in the row direction and arranged in the column direction;
wherein at least part of pixel circuits located in a same row are electrically connected to a same first signal line; and
at least one first signal line among the plurality of first signal lines is disposed between the power connection line and the pixel circuit.

20. A display device, comprising a display panel, wherein the display panel comprises:
a plurality of pixel units arranged in an array, a plurality of power signal lines, and a plurality of data signal lines; wherein
a pixel unit among the plurality of pixel units comprises a plurality of sub-pixels of different emission colors, and a sub-pixel among the plurality of sub-pixels comprises a pixel circuit and a light-emitting element electrically connected to each other;
pixel circuits in two adjacent columns are electrically connected to a same data signal line; and
the plurality of power signal lines are arranged in a row direction of the plurality of pixel units and extend in a column direction of the plurality of pixel units, and a distance between two adjacent power signal lines is Ll, Ll≥Lp, and Lp is a dimension of one of the plurality of pixel units in the row direction.
